(19) United States
(12) Patent Application Publication
(10) Pub. No.: US 2004/0044824 A1
(43) Pub. Date: Mar. 4, 2004

(54) Information processing method, information processing apparatus, and program therefor

(76) Inventors: Naoya Haneda, Tokyo (JP); Kyoya Tsutsui, Kanagawa (JP)

Correspondence Address: FROMMER LAWRENCE & HAUG LLP, 745 FIFTH AVENUE, NEW YORK, NY, 10151, US

(21) Appl. No.: 10/649,158

(22) Filed: Aug. 27, 2003

(30) Foreign Application Priority Data
Aug. 30, 2002 (JP) P2002-253355

(51) Int. Cl. G11C 5/00

(52) U.S. Cl. 711/1

(57) ABSTRACT

An information processing method separates tone component information higher than a trial frequency band and quantization accuracy information and normalization coefficient information of non-tone components higher than the trial frequency band. The number of tone components and the number of quantization units are minimized (to zero), and the other data is arranged in an extended area that cannot be referred to by a known player. Trial time information is written in an area containing unreferenced spectral coefficient information, which may be replaced, where necessary, with dummy data. A player for playing trial data refers to the trial time information, selects a random portion(s) from a trial-permitted area(s), the total playback time being within the trial time, and rearranges data included in the extended area of each selected frame at a playable position, thus playing the trial data. The present invention is applicable to encoders, data players, and data recorders.

### BACKGROUND OF THE INVENTION

1. Field of the Invention

The present invention relates to information processing methods, information processing apparatuses, recording media, and programs therefor, and more particularly relates to an information processing method, an information processing apparatus, a recording medium, and a program therefor for use in distribution of trial data of content to users.

2. Description of the Related Art

Due to the widespread use of communication network technology including the Internet, improvement of information compression technology, and advances in enhancing integration or increasing density of information recording media, paid distribution of digital content including various multimedia data, such as audio, still images, moving images, and movies containing audio and moving images, to users on a trial basis has been conducted via communication networks.

For example, a store that sells packaged media, such as CDs (Compact Disk) or MDs (Mini-Disk) (trademark), which are recording media having digital content recorded thereon in advance, is equipped with, for example, an information terminal, such as a so-called multi-media kiosk (MMK). The MMK stores many pieces of digital content including music data. This enables the store to sell packaged media and digital content.

A user brings a recording medium, e.g., an MD, to the store and inserts the recording medium into the MMK. The user then refers to a menu screen or the like, selects the title of digital content to purchase, and pays the amount required for the digital content. Possible methods of payment include cash, electronic money, and electronic transaction using a credit card or prepaid card. The MMK performs predetermined processing to record the selected digital content data onto the recording medium inserted by the user.

As described above, using the MMK, digital content sellers may sell digital content to users. In addition, the digital content sellers may distribute digital content to users via, for example, the Internet.

Content is efficiently distributed not only by selling packaged media having the content recorded thereon but also by selling the digital content itself.

In order to distribute digital content while protecting the copyright, for example, the technology described in Japanese Unexamined Patent Application Publication No. 2001-103047 or No. 2001-325460 is used to encrypt portions of the digital content other than a trial-permitted portion, and then the digital content is distributed. Only a user who has purchased a decryption key for the encryption is permitted to listen to the entire content on a trial basis. One known encryption method involves, for example, generating an initial random sequence of 0's and 1's serving as a decryption key for a bit stream of pulse coded modulation (PCM) digital audio data, computing the exclusive-OR of the generated random sequence and the PCM data to be distributed, and regarding the exclusive-OR as an encrypted bit stream. The digital content encrypted in this manner is recorded on a recording medium using, for example, the above-described MMK or is distributed via a network to a user. Unless the user who has obtained the encrypted digital content data has a key for the encrypted digital content data, the user is only permitted to listen to an unencrypted, trial-permitted portion. When the encrypted portion is played without being decrypted, all the user hears is noise.

Technologies for compressing audio data or the like, broadcasting the compressed audio data, distributing the compressed audio data via a network, and recording the compressed data onto various recording media including magneto-optical disks have been improved.

There are various possible methods of highly efficient encoding of audio data: sub-band coding (SBC) in which, instead of dividing an audio signal in the time domain into blocks, the audio signal is divided into multiple frequency bands (sub-bands) and the sub-bands are encoded; and blocking sub-band coding, or so-called transform coding, in which a spectral transform of a signal in the time domain is performed to generate a signal in the frequency domain, the signal is divided into multiple sub-bands, and each of the sub-bands is encoded. There is another method in which, after dividing the signal into sub-bands by SBC, a spectral transform of the signal in each of the sub-bands is performed to transform it into a frequency-domain signal and each of the spectral-transformed sub-bands is encoded.

One filter used in the above cases is, for example, a quadrature mirror filter (QMF). For QMF, see R. E. Crochiere, “Digital Coding of Speech in Subbands” (Bell Syst. Tech. J., Vol. 55, No. 8, 1974). Joseph H. Rothweiler, “Polyphase Quadrature Filters—a New Subband Coding Technique” (ICASSP 83, BOSTON) provides details on a filter for splitting a signal into equidistant sub-bands.

A method of performing the above-described spectral transform involves, for example, dividing an input audio signal into blocks of predetermined unit time (frames) and performing a discrete Fourier transform (DFT), a discrete cosine transform (DCT), a modified DCT (MDCT), or the like on each block. For the details of MDCT, see J. P. Princen and A. B. Bradley, (Univ. of Surrey, Royal Melbourne Inst. of Tech.), “Subband/Transform Coding Using Filter Bank Designs Based on Time Domain Aliasing Cancellation” (ICASSP 1987).

When the above-described DFT or DCT is used as a method of performing a spectral transform of a waveform signal, if the transform is performed on time blocks each of which consists of M samples, then M independent pieces of real data are generated. In order to alleviate connection distortion between the time blocks, normally one block is overlapped with N/2 samples in each of its adjacent blocks, that is, a total of N samples in two adjacent blocks. In DFT or DCT, on average M pieces of independent real data are quantized and encoded for the (M+N) samples.

In contrast, when the above-described MDCT is used as a method of performing a spectral transform, if the transform is performed on time blocks each of which consists of M samples, M pieces of independent real data are generated from 2M samples consisting of M samples in one block and M/2 samples in each of its adjacent blocks, that is, M samples in two adjacent blocks. In MDCT, on average, M pieces of real data are quantized and encoded for the M samples.

The decoder recovers the original waveform signal from codes generated using MDCT by adding waveform components generated by inverse-transforming the blocks while letting them interfere with one another.

In general, the longer a time block in a transform, the higher the spectral frequency resolution becomes. As a result, energy is concentrated in a specific spectral component. By overlapping one block with half of each of its adjacent blocks, the transform is performed with a long block length. The transform is performed using MDCT in which the number of spectrum signals generated does not increase relative to the number of time samples used as the base. Compared with a transform using DFT or DCT, coding is done more efficiently. By overlapping one block with a sufficiently long portion of each of its adjacent blocks, distortion between the blocks of the waveform signal is alleviated.

As described above, sub-band signals generated by filtering and spectral transformation are quantized to control the bandwidth in which quantization noise occurs. Using a masking effect or the like, coding is performed more efficiently in terms of hearing perception. Prior to quantization, normalization is performed in each sub-band on the basis of, for example, the maximum absolute value of signal components in that sub-band. Accordingly, highly efficient coding is performed.

In quantization of frequency components generated by sub-band coding, for example, the bandwidth of each sub-band may be determined by taking into consideration human hearing characteristics. In other words, an audio signal may be divided into multiple sub-bands (e.g, 25 bands), in which higher bands generally referred to as critical bands have broader bandwidth.

In a case in which the bandwidth is divided so that the critical bands become broader, encoding of data in each sub-band may involve a predetermined bit allocation in each sub-band or an adaptive bit allocation in each sub-band.

For example, coefficient data generated by MDCT is encoded by bit allocation involving allocating an adaptive number of bits to the MDCT coefficient data in each sub-band generated by MDCT of each block. For example, the following are two known techniques for bit allocation.

R. Zelinski and P. Noll, “Adaptive Transform Coding of Speech Signals” (IEEE Transactions of Acoustics, Speech, and Signal Processing, Vol. ASSP-25, No. 4, August 1977) provides details on bit allocation based on the level of a signal in each sub-band. According to this technique, the spectrum of quantization noise becomes flat, and noise energy is minimized. In terms of hearing perception, this technique is not optimal for reducing noise audible to the human ear since a masking effect is not used.

M. A. Kransner (Massachusetts Institute of Technology), “The Critical Band Coder Digital Encoding of the Perceptual Requirements of the Auditory System” (ICASSP 1980) describes a technique for fixed bit allocation by using auditory masking to determine the necessary signal-to-noise ratio in each sub-band. With this technique, when the characteristics of an input sine wave are measured, the characteristic value is not very satisfactory since the bit allocation is fixed.

In order to solve these problems, a highly efficient encoder is proposed. In the highly efficient encoder, all bits available to be allocated are divided into bits for a fixed bit allocation pattern predetermined in each small block and bits to be allocated depending on the level of a signal in each block. The division ratio depends on a signal associated with an input signal. The division ratio is set so that the smoother the spectrum of the signal, the more bits are allocated to the fixed bit allocation pattern.

In a case where energy is concentrated in a specific spectrum, such as in an input of a sine wave, the use of this method allows many bits to be allocated to a block including that spectrum. As a result, the overall signal-to-noise characteristics are greatly improved. In general, human hearing is extremely sensitive to signals with steep spectral components. Improvement of the signal-to-noise characteristics using such a method is effective to improve not only the measured characteristic values but also the quality of sound audible to the human ear.

In addition to the above-described method, many other bit allocation methods are proposed. Due to elaboration of the auditory model and improvement of the performance of the encoder, more highly efficient coding is made possible that takes into consideration the measured characteristic values and human hearing perception. Such methods generally compute a real number serving as a bit-allocation reference that realizes the calculated signal-to-noise characteristics as faithfully as possible. An integer approximating the real number is computed. The number of bits to be allocated is set to the computed integer.

Japanese Patent Application No. 5-152865 or WO94/28633, filed by the inventors of the present invention, describes an encoding method that separates tone components that are particularly important in terms of hearing perception, i.e., components in which energy is concentrated in the vicinity of a specific frequency, and encodes the separated tone components separately from other spectral components. With this method, an audio signal or the like is efficiently encoded at a high compression ratio without degrading the audible part of the signal.

In generation of the actual code string, quantization accuracy information and normalization coefficient information in each sub-band to be normalized and quantized are encoded using a predetermined number of bits, and then the normalized and quantized spectrum signals are encoded. ISO/IEC 11172-3 (1993(E), a933) describes highly efficient coding in which different numbers of bits representing quantization accuracy information are assigned to different bands. The standard defines that the higher the band, the fewer the bits representing the quantization accuracy information.

In another known method, instead of directly encoding the quantization accuracy information, the decoder determines, for example, the quantization accuracy information from the normalization coefficient information. According to this method, the relationship between the normalization coefficient information and the quantization accuracy information is determined at the time the scheme is determined. This eliminates the future possibility of adopting control measures using quantization accuracy based on a higher auditory model. When the compression ratio to be achieved ranges widely, it becomes necessary to define the relationship between the normalization coefficient information and the quantization accuracy information for each compression ratio.

One known method of encoding the quantized spectrum signals in a more efficient manner is described in, for example, D. A. Huffman, “A Method for Construction of Minimum Redundancy Codes” (Proc. I.R.E., 40, p. 1098, 1952) describing efficient coding using a variable-length code.

Content data that has been encoded using one of the above-described methods may be encrypted, as in the case of the PCM signal, and then distributed. Such a content protection method prevents a user who does not have a key signal from playing the original signal. There is another method in which, instead of encrypting an encoded bit stream, the PCM signal is transformed into a random signal and then the random signal is encoded for compression. When this content protection method is used, a user who does not have a key signal is only capable of playing noise.

Distribution of trial data of content data promotes sales of the content data. The trial data includes, for example, data that is played with lower sound quality than that of the original data and data for playing part of the original data (e.g., only the refrain of the original piece of music). A user of the content data plays the trial data and, if the user likes what he or she has heard, the user purchases a key for decrypting the encryption. With the key, the user can play the original music or download the original audio data. The user may even purchase a recording medium having the original audio data recorded thereon.

With the above-described content protection methods, the complete data cannot be played, or the complete data is played as noise. These content protection methods cannot be used in distribution of recording media storing audio data recorded with a relatively low sound quality. Even when data scrambled by one of these methods is distributed to a user, the user cannot understand the outline of the complete data.

According to the known methods, generally it is extremely difficult to encrypt a highly-efficiently-encoded signal by supplying a code string that is meaningful to widely used players while not reducing the compression efficiency. In other words, as described above, in a case where a code string generated by highly efficient coding is scrambled, playing the scrambled code string without de-scrambling it generates only noise. What is worse, when the scrambled code string does not comply with the original highly efficient coding scheme, playback may be completely prohibited.

In contrast, when the PCM signal is scrambled and the scrambled PCM signal is highly efficiently encoded, reducing the amount of information on the basis of, for example, auditory characteristics, results in irreversible coding. Even when such highly efficient codes are decoded, the scrambled PCM signal is not correctly recovered. In other words, de-scrambling of such a signal is very difficult to perform.

Therefore, a method for correctly de-scrambling a signal has been chosen although the compression efficiency is low.

In view of the above-described problems, the inventors of the present invention describe an audio coding method in Japanese Unexamined Patent Application Publication No. 10-135944. In this audio coding method, for example, music data is transformed into spectrum signals and the spectrum signals are encoded. Of the encoded spectrum signals, only codes associated with high frequency bands are encrypted. Data generated as such is distributed as trial data. Accordingly, even a user who does not have a key is permitted to decode and play an unencrypted narrowband portion of the signal. According to this method, codes at high frequencies are encrypted, and bit allocation information at high frequencies is replaced with dummy data. The true bit allocation information at high frequencies is recorded at positions at which information is not read (ignored) by a decoder serving as a player when playing information.

When this method is adopted, a user of the content data receives the distributed trial data, plays the trial data, and, as a result of listening to the trial data, purchases (pays for) a key for decrypting the favorite trial data into the original data. The user can thus play desired music content in all bands correctly, allowing the user to enjoy the music with high sound quality.

With the technology described in Japanese Unexamined Patent Application Publication No. 10-135944, a user who does not have the key is only permitted to decode a narrowband signal of the data distributed free of charge. Since the security of the content depends only on the encryption, a user who succeeds in decrypting the encryption may play the music with high sound quality without paying for it. A distributor of the music data (content provider) cannot collect money for such content.

The content provider may want to offer a trial, not by permitting a quality-limited trial of the entire content, but by permitting a quality-limited trial of part or parts of the content. In this case, a trial of the remaining part of the content may not be permitted even if the quality of the remaining part is limited.

For example, when trial data is distributed free-of-charge to a user by allowing playback of part of a piece of music for ten seconds or so, the user must be prevented from playing the remaining part of the piece of music. The user must determine whether to purchase the entire content after listening to only the predetermined short part of the piece of music. In other words, such trial data is not sufficient for encouraging the user to purchase.

### SUMMARY OF THE INVENTION

In view of these circumstances, it is an object of the present invention to offer, upon distribution of trial data of content data, a trial of various parts of the content data within a predetermined period of time and to recover the original data from the trial data using small volume of data.

A first information processing method of the present invention includes a generation step of generating a third data stream from a second data stream on the basis of a predetermined condition; and a first control step of controlling playback or recording of the third data stream. The second data stream has an arrangement that cannot be played or recorded without changing the arrangement. The third data stream is generated in the generation step by rearranging, on the basis of the predetermined condition, the second data stream so that the rearranged second data stream is playable or recordable.

The predetermined condition may include a condition concerning the play time or the recording time controlled in the first control step.

In the generation step, the third data stream may be generated so that playback or recording of an arbitrary portion of the third data stream is controlled in the first control step.

The second data stream may include a plurality of frames, the plurality of frames including a first frame type that has a data arrangement in which data cannot be played or recorded without changing the arrangement. In the generation step, a second frame type may be selected from the first frame type of the second data stream, and data in the second frame type may be rearranged so that the data in the second frame type becomes playable or recordable.

The predetermined condition may include the upper limit of the play time or the recording time controlled in the first control step. In the generation step, a plurality of frames of the second frame type, which are playable or recordable within the play time or the recording time, may be selected from the first frame type included in the second data stream on the basis of the predetermined condition, and data in the selected frames may be rearranged.

In the generation step, the frames of the second frame type may be selected from a plurality of portions of the second data stream so that the total play time or the total recording time is within the play time or the recording time.

The predetermined condition may include information concerning the start position of playback or recording controlled in the first control step.

The first information processing method may further include a storage control step of controlling storage of information indicating the predetermined condition.

The first information processing method may further include an obtaining control step of controlling the obtaining of information indicating the predetermined condition from the second data stream.

The first information processing method may further include an obtaining control step of controlling the obtaining of a fourth data stream including information required to recover the first data stream from the second data stream; a recovering step of recovering the first data stream from the second data stream on the basis of the fourth data stream, the obtaining of which is controlled in the obtaining control step; and a second control step of controlling playback or recording of the first data stream recovered in the recovering step.

The fourth data stream, the obtaining of which may be controlled in the obtaining control step, may include first data required to recover the first data stream. In the recovering step, the first data stream may be recovered by replacing part of the first data included in the fourth data stream with second data included in the second data stream.

The second data may be written in the second data stream at a position not referred to when the third data stream is generated from the second data stream in the generation step and when playback or recording of the third data stream is controlled in the first control step.

The second data stream may be an encoded data stream. The first data may include a variable-length code.

The first information processing method may further include an inverse-transformation step of inverse-transforming frequency components. The second data stream may be a data stream generated by being transformed into frequency components and then being encoded. The first data may include spectral coefficient information.

The first information processing method may further include a decoding step of decoding the second data stream. When the second data is decoded in the decoding step, the data length of the decoded second data may be shorter than the data length of the decoded first data.

The second data stream is an encoded data stream, and the first data may include the number of quantization units.

The second data stream may be a data stream generated by being separated into first signals and second signals and then being encoded, and the first data may include the number of separated first signals.

The fourth data stream, the obtaining of which may be controlled in the obtaining control step, may include data required to recover the first data stream. In the recovering step, the first data stream may be recovered by inserting part of the data included in the fourth data stream into the second data stream.

The second data stream may be an encoded data stream, and the data included in the fourth data stream may include normalization coefficient information.

The second data stream may be an encoded data stream, and the data included in the fourth data stream may include quantization accuracy information.

The first information processing method may further include a decoding step of decoding the third data stream. In the first control step, playback or recording of the third data stream decoded in the decoding step may be controlled. The second data stream may be an encoded data stream.

A first information processing apparatus of the present invention includes a generation unit for generating a third data stream from a second data stream on the basis of a predetermined condition; and a control unit for controlling playback or recording of the third data stream.

The first information processing apparatus may further include a storage unit for storing the predetermined condition.

A program recorded on a first storage medium of the present invention includes a generation step of generating a third data stream from a second data stream on the basis of a predetermined condition; and a control step of controlling playback or recording of the third data stream.

A first program of the present invention includes a generation step of generating a third data stream from a second data stream on the basis of a predetermined condition; and a control step of controlling playback or recording of the third data stream.

A second information processing method of the present invention includes a first replacement step of replacing first data included in a first data stream with second data to generate a third data stream; a changing step of changing the arrangement of third data included in the third data stream generated in the first replacement step; an insertion step of inserting information indicating a condition for playback or recording of a second data stream into the third data stream in which the arrangement of the third data is changed in the changing step; and a first generation step of generating the second data stream on the basis of the third data stream including the information indicating the condition, the information being inserted in the insertion step. In the changing step, the third data recorded in a first area of the third data stream is moved to a second area.

The first area may be an area that is in the third data stream and that is associated with an area referred to during playback or recording of the second data stream generated in the first generation step. The second area may be an area that is in the third data stream and that is associated with an area not referred to during playback or recording of the second data stream generated in the first generation step.

The second area may be an area that is in the third data stream and that, by replacing the first data with the second data in the first replacement step, becomes associated with an area not referred to during playback or recording of the second data stream.

The first data may be data concerning the number of pieces of information referred to during playback or recording of the second data stream. In the first replacement step, the first data may be replaced with the second data indicating that there is no information referred to during playback or recording of the second data stream.

The first data stream, the second data stream, and the third data stream each may include a plurality of frames. In the insertion step, the information indicating the condition may be inserted into at least one of the plurality of frames of the third data stream. The frames included in the second data stream generated in the first generation step may include information indicating whether or not the information indicating the condition is inserted in the insertion step.

The information indicating the condition, which may be inserted into the third data stream in the insertion step, may include a condition concerning the play time or the recording time when playing or recording the second data stream.

The information indicating the condition, which may be inserted into the third data stream in the insertion step, may include information concerning the start position of playback or recording when playing or recording the second data stream.

The second information processing method may further include a separation step of separating fourth data from the first data stream, the fourth data differing from the first data and the third data.

The second information processing method may further include an encoding step of encoding input data. The fourth data may include normalization coefficient information on the encoding in the encoding step.

The second information processing method may further include an encoding step of encoding input data. The fourth data may include quantization accuracy information on the encoding in the encoding step.

The second information processing method may further include a second generation step of generating a fourth data stream required to recover the first data stream from the second data stream generated in the first generation step. The fourth data stream generated in the second generation step may include the first data replaced with the second data in the first replacement step.

The second information processing method may further include a separation step of separating fourth data from the first data stream, the fourth data differing from the first data and the third data. The fourth data stream generated in the second generation step may further include the fourth data separated in the separation step.

The second information processing method may further include an encoding step of encoding input data. In the first replacement step, encoded data encoded in the encoding step may serve as the first data stream, and the first data included in the first data stream may be replaced with the second data.

The first data may include information indicating the number of quantization units in the encoding in the encoding step.

The second information processing method may further include a frequency component transformation step of transforming input data into frequency components; and a separation step of separating the frequency components generated by transformation in the frequency component transformation step into first signals including tone components and second signals other than the first signals. In the encoding step, different encoding processes may be performed on the first signals and the second signals.

The first data may be data indicating the number of first signals separated in the separation step.

The second information processing method may further include a second replacement step of replacing fourth data with fifth data, the fourth data differing from the first data included in the first data stream. The fifth data may be associated with data not referred to during playback or recording of the second data. In the changing step, the arrangement of the third data included in the third data stream in which the fourth data is replaced with the fifth data in the second replacement step may be changed.

The fifth data may be generated by replacing at least part of the fourth data with random data.

The second information processing method may further include a second generation step of generating a fourth data stream required to recover the first data stream from the second data stream generated in the first generation step. The fourth data stream generated in the second generation step may include the fourth data replaced with the fifth data in the second replacement step and position information indicating the position of the fourth data in the first data stream.

The second information processing method may further include an encoding step of encoding data. When the fifth data is decoded, the data length of the decoded fifth data may be shorter than the data length of the decoded fourth data.

The second information processing method may further include an encoding step of encoding data. The fourth data may include a variable-length code.

A second information processing apparatus of the present invention includes a replacement unit for replacing first data included in a first data stream with second data to generate a third data stream; a changing unit for changing the arrangement of third data included in the third data stream generated by the replacement unit; an insertion unit for inserting information indicating a condition for playback or recording of a second data stream into the third data stream in which the arrangement of the third data is changed by the changing unit; and a generation unit for generating the second data stream on the basis of the third data stream including the information indicating the condition, the information being inserted by the insertion unit. The changing unit moves the third data recorded in a first area of the third data stream to a second area.

A program recorded on a second recording medium of the present invention includes a replacement step of replacing first data included in a first data stream with second data to generate a third data stream; a changing step of changing the arrangement of third data included in the third data stream generated in the replacement step; an insertion step of inserting information indicating a condition for playback or recording of a second data stream into the third data, stream in which the arrangement of the third data is changed in the changing step; and a generation step of generating the second data stream on the basis of the third data stream including the information indicating the condition, the information being inserted in the insertion step. In the changing step, the third data recorded in a first area of the third data stream is moved to a second area.

A second program of the present invention includes a replacement step of replacing first data included in a first data stream with second data to generate a third data stream; a changing step of changing the arrangement of third data included in the third data stream generated in the replacement step; an insertion step of inserting information indicating a condition for playback or recording of a second data stream into the third data stream in which the arrangement of the third data is changed in the changing step; and a generation step of generating the second data stream on the basis of the third data stream including the information indicating the condition, the information being inserted in the insertion step. In the changing step, the third data recorded in a first area of the third data stream is moved to a second area.

According to the first information processing method, information processing apparatus, and program of the present invention, a third data stream is generated from a second data stream on the basis of a predetermined condition, and playback or recording of the third data stream is controlled.

According to the second information processing method, information processing apparatus, and program of the present invention, a third data stream is generated by replacing first data included in a first data stream with second data. Third data recorded in a first area of the third data stream is moved to a second area, thus changing the arrangement of the third data. Information indicating a condition for playback or recording of the second data stream is inserted into the third data stream in which the arrangement of the third data is changed. The second data stream is generated on the basis of the third data stream including the information indicating the condition.

According to the present invention, a data stream can be recorded or played. Data that cannot be played or recorded without changing the arrangement is rearranged to recover a playable data stream. The data stream can thus be recorded or played.

According to the present invention, in addition that a data stream can be transformed, data that cannot be played or recorded by a known data player or a known data recorder is rearranged by a predetermined apparatus to generate a playable or recordable data stream.

According to the present invention, a user can check the quality and details of the entire music content before purchasing the music content. A music signal on which a message signal has been superimposed is played as a trial playback signal, or narrowband playback of at least part of the music signal is performed. This prevents copying of a high quality signal provided for a trial, and hence authorized dealers and distributors of content, such as music, do not have to stop selling their products for the fear of not being able to collect fees for their products. The above-described advantages are achieved not only in the case of music products, but also in the case of general signal code strings including image signals.

### BRIEF DESCRIPTION OF THE DRAWINGS

FIG. 1 is a diagram describing a data exchange system including an encoder, data players, and data recorders according to the present invention;

FIG. 2 is a block diagram of the configuration of the encoder according to the present invention;

FIG. 3 is a block diagram of the configuration of a transform unit shown in FIG. 2;

FIG. 4 is a diagram describing spectrum signals and quantization units;

FIG. 5 is a block diagram of the configuration of a signal component encoder shown in FIG. 2;

FIG. 6 is a diagram describing tone components and non-tone components;

FIG. 7 is a block diagram of the configuration of a tone component encoder shown in FIG. 5;

FIG. 8 is a block diagram of the configuration of a non-tone component encoder shown in FIG. 5;

FIG. 9 is a diagram of the format of a frame of original data;

FIG. 10 is a block diagram of the configuration of a trial data generator shown in FIG. 2;

FIG. 11 includes diagrams describing trial-permitted areas and trial-prohibited areas of an input frame sequence;

FIG. 12 is a diagram describing data to be separated;

FIG. 13 is a diagram describing trial audio spectrum signals;

FIG. 14 is a diagram describing a trial frame;

FIG. 15 is a diagram describing an additional frame;

FIG. 16 is a flowchart describing a trial data generating process;

FIG. 17 is a flowchart describing the trial data generating process;

FIG. 18 is a flowchart describing the trial data generating process;

FIG. 19 is a diagram describing a frame of the original data when the tone components are not separated;

FIG. 20 is a diagram describing the data to be separated;

FIG. 21 is a diagram describing the trial frame when the tone components are not separated;

FIG. 22 is a diagram describing the additional frame when the tone components are not separated;

FIG. 23 is a block diagram of the configuration of the data player according to the present invention;

FIG. 24 is a block diagram of the configuration of a signal component decoder shown in FIG. 23;

FIG. 25 is a block diagram of the configuration of a tone component decoder shown in FIG. 24;

FIG. 26 is a block diagram of the configuration of a non-tone component decoder shown in FIG. 24;

FIG. 27 is a block diagram of the configuration of an inverse transform unit shown in FIG. 23;

FIG. 28 is a flowchart describing a playback process;

FIG. 29 is a flowchart describing a trial-data playback process;

FIG. 30 is a flowchart describing a high-quality data playback process;

FIG. 31 is a flowchart describing an original-data recovering process;

FIG. 32 is a block diagram of the configuration of the data recorder according to the present invention;

FIG. 33 is a flowchart describing a data recording process;

FIG. 34 is a flowchart describing the data recording process;

FIG. 35 is a block diagram of the configuration of a personal computer;

FIG. 36 is a diagram showing an example of a signal decoded and played in trial playback according to the present invention;

FIG. 37 is a block diagram of an example of a signal player according to the present invention;

FIG. 38 is a block diagram of an example of another signal player according to the present invention;

FIG. 39 is a diagram describing an example of a code string applicable to the present invention;

FIG. 40 is a block diagram of an example of a code string rearranged by a method according to the present invention;

FIG. 41 is a flowchart showing an example of a signal playback process according to the present invention; and

FIG. 42 is a flowchart showing an example of another signal playback process according to the present invention.

### DESCRIPTION OF THE PREFERRED EMBODIMENTS

With reference to the accompanying drawings, embodiments of the present invention will be described.

First Embodiment

A first embodiment according to the present invention will now be described.

A case is described in which an input of a digital signal, such as an audio PCM signal, is received and highly efficient coding is performed by subjecting the received signal to sub-band coding (SBC), adaptive transform coding (ATC), and adaptive bit allocation. ATC is a coding method involving adaptive bit allocation based on a discrete cosine transform (DCT) or the like. ATC transforms an input signal into spectrum signals every time block, normalizes a set of the spectrum signals in each predetermined band (sub-band), that is, divides each signal component by a normalization coefficient approximating the maximum signal component, quantizes the normalized signal components with quantization accuracy that is appropriately determined on the basis of the signal characteristics, and encodes the quantized signal components.

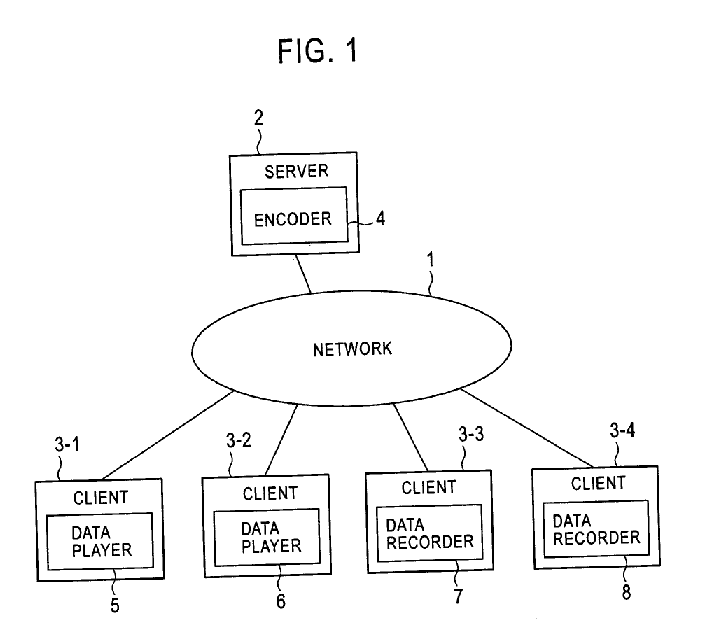

FIG. 1 shows a data exchange system including an encoder, data players, and data recorders according to the present invention.

A server 2 transmits trial data of content or additional data, which has been encoded by an encoder 4, via a network 1 to clients 3-1 to 3-4. When added to the trial data, the additional data can generate original data. The detailed configuration of the encoder 4 will be described later. The trial data generated by the encoder 4 cannot be recorded or played by a known recorder/player capable of recording and playing, for example, audio data generated by ATRAC3 (trademark) or the like. The trial data can be played only by a data player 5 and can be recorded only by a data recorder 7, which will be described later.

The client 3-1 includes the data player 5, which will be described later. The data player 5 receives a supply of the trial data via the network 1 and plays the trial data by performing predetermined processing of the trial data. Also, the data player 5 receives a supply of the additional data, generates the original data from the trial data and the additional data, and plays the original data. In contrast, a data player 6 included in the client 3-2 is a known apparatus for playing known audio data generated by ATRAC3 or the like. Although the data player 6 can play the original data, the data player 6 cannot play the trial data.

The client 3-3 has the data recorder 7, which will be described later. The data recorder 7 receives a supply of the trial data and records the trial data onto a recording medium, such as a magneto-optical disk, by performing predetermined processing of the trial data. Also, the data recorder 7 receives a supply of the additional data, generates the original data from the trial data and the additional data, and records the original data. In contrast, a data recorder 8 included in the client 3-4 is a known apparatus for recording audio data generated by, for example, ATRAC3 or the like. Although the data recorder 8 can record the original data, the data recorder 8 can neither record the trial data nor receive a supply of the additional data and generate the original data from the trial data and the additional data.

In the above description, the clients 3-1 to 3-4 each have a data player or a data recorder. Alternatively, a client may include both a data player and a data recorder. A client that has the data player 5 and the data recorder 7 can play and record the trial data supplied by the server 2 via the network 1 and can receive a supply of the additional data, generate the original data from the trial data and the additional data, and record or play the original data.

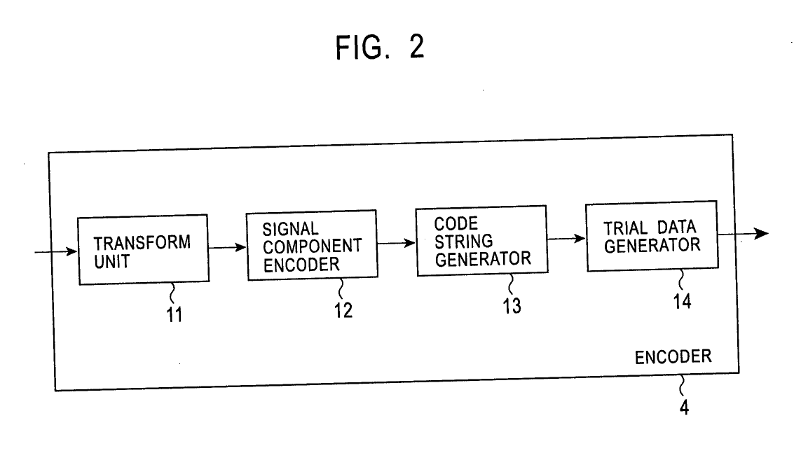

FIG. 2 is a block diagram of an example of the configuration of the encoder 4 for receiving an input of an acoustic waveform signal and generating trial data.

A transform unit 11 receives an input of an acoustic waveform signal, transforms the received acoustic waveform signal into signal frequency components, and outputs the signal frequency components to a signal component encoder 12. The signal component encoder 12 encodes the input signal frequency components and outputs the encoded signal frequency components to a code string generator 13. The code string generator 13 generates a code string from the signal frequency components encoded by the signal component encoder 12 and outputs the code string to a trial data generator 14. The trial data generator 14 performs predetermined processing of the code string input by the code string generator 13, such as rearrangement of normalization coefficient information of the code string and insertion of trial time information into the code string, thus converting audio data (original data) that can be played with high sound quality into trial data. Also, the trial data generator 14 generates and outputs additional data (recovering data) that is associated with the trial data and that is sold to a user who wants to play the original data.

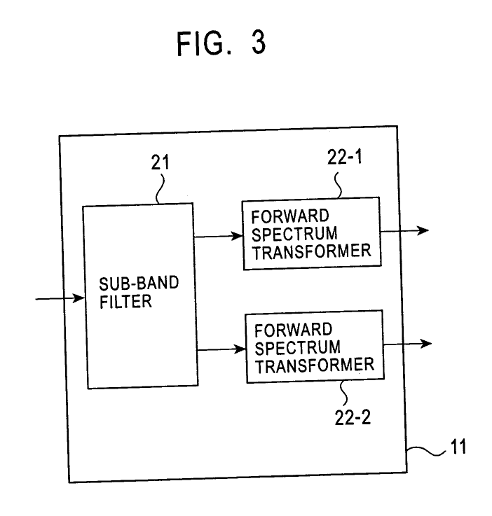

FIG. 3 is a block diagram of the more detailed configuration of the transform unit 11.

The acoustic waveform signal input to the transform unit 11 is divided into two sub-bands by a sub-band filter 21, and the resultant two sub-band signals are output to forward spectrum transformers 22-1 and 22-2, respectively. Using a modified discrete cosine transform (MDCT) or the like, the forward spectrum transformers 22-1 and 22-2 transform the input signals into spectrum signal components and output the spectrum signal components to the signal component encoder 12. The bandwidth of the signals input to the forward spectrum transformers 22-1 and 22-2 is half the bandwidth of the signal input to the sub-band filter 21, and the input of signals is decimated to half.

In the transform unit 11 shown in FIG. 3, it has been described that the signal divided into two sub-bands by the sub-band filter 21 is transformed into spectrum signal components using MDCT. Any type of method can be used to transform the input signal into spectrum signal components. For example, the input signal is not divided into sub-bands, and the input signal is transformed into spectrum signal components using MDCT. Alternatively, the forward spectrum transformers 22-1 and 22-2 may transform the input signals into spectrum signals using DCT or discrete Fourier transform (DFT).

Although the input signal may be divided into sub-band components using a so-called sub-band filter, it is preferable to perform spectrum transformation using MDCT, DCT, or DFT capable of calculating many frequency components with relatively small calculation.

Referring to FIG. 3, it has been described that the input acoustic waveform signal is divided into two sub-bands by the sub-band filter 21. The number of sub-bands is not limited to two. Information indicating the number of sub-bands for the sub-band filter 21 is output via the signal component encoder 12 to the code string generator 13.

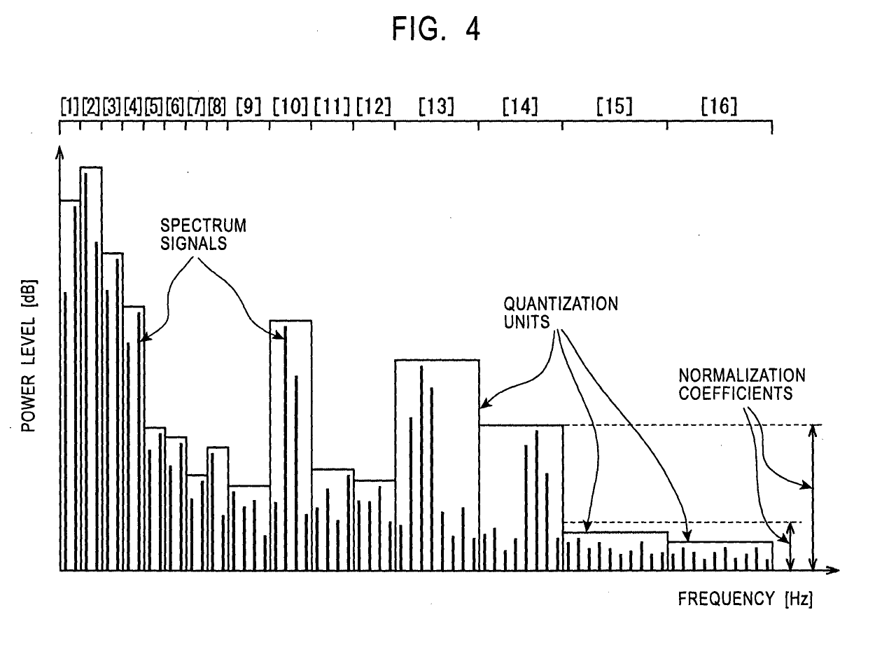

FIG. 4 shows, in power level, the absolute values of the spectrum signals generated by the transform unit 11 using MDCT. The acoustic waveform signal input to the transform unit 11 is transformed into, for example, 64 spectrum signals every predetermined time block. These spectrum signals are processed by the signal component encoder 12, which will be described later, and divided into, for example, sixteen sub-bands represented by sixteen frames [1] to [16] denoted by the solid lines in FIG. 4. In each sub-band, quantization and normalization are performed. A set of the spectrum signals in each of the sixteen sub-bands, that is, a set of the spectrum signals to be quantized and normalized, is referred to as a quantization unit.

Quantization accuracy is changed in each quantization unit on the basis of the distribution of the frequency components, thus achieving highly efficient coding that minimizes quality degradation of sound that is audible to the human ear.

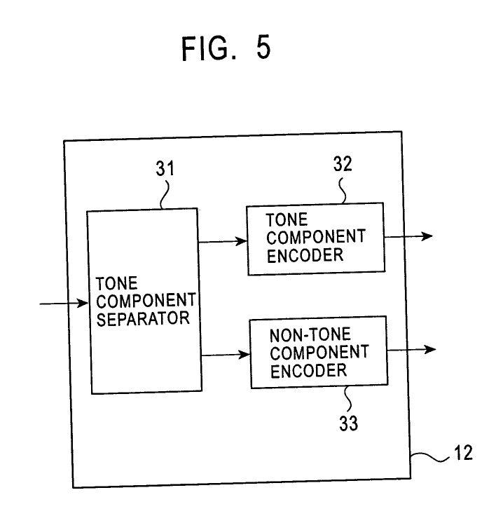

FIG. 5 is a block diagram of the detailed configuration of the signal component encoder 12. A case is described in which the signal component encoder 12 separates perceptually important tone portions, that is, signal components in which energy is concentrated in the vicinity of a specific frequency, from the input spectrum signals and encodes these tone portions separately from other spectral components.

The spectrum signals input by the transform unit 11 are separated by a tone component separator 31 into tone components and non-tone components. The tone components are output to a tone component encoder 32. The non-tone components are output to a non-tone component encoder 33.

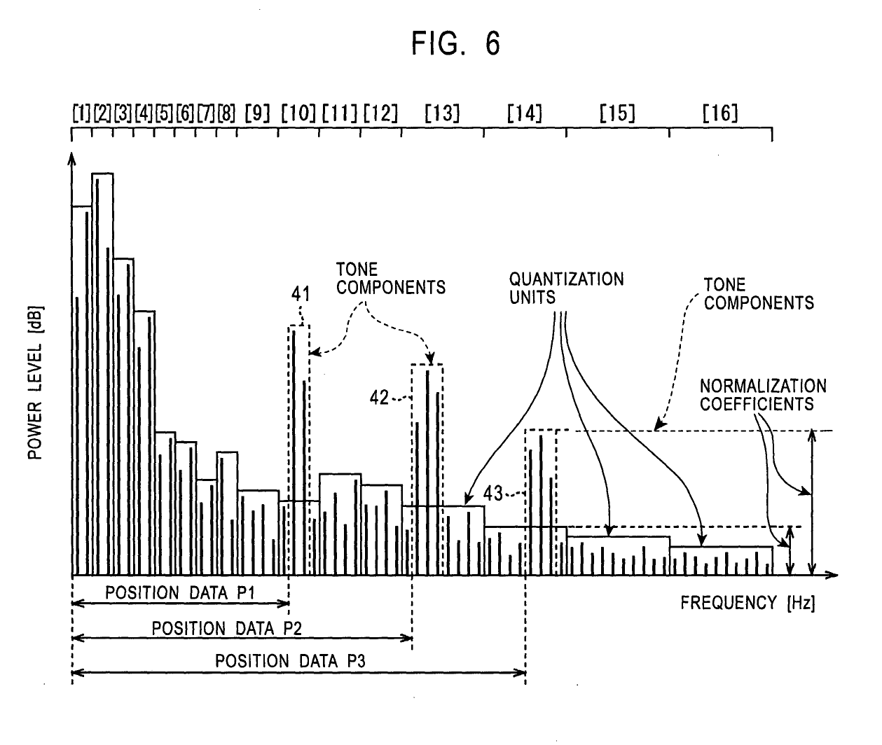

Referring to FIG. 6, the tone components and the non-tone components will be described. For example, when the spectrum signals input to the tone component separator 31 are signals such as those shown in FIG. 6, portions that are particularly high in power level are separated as tone components 41 to 43 from non-tone components. Position data P1 to P3 indicating the positions of the separated tone components 41 to 43 and the width of frequencies separated as the tone components are detected and output, together with the tone components 41 to 43, to the tone component encoder 32.

The tone components may be separated by, for example, a method described in Japanese Patent Application No. 5-152865, WO94/28633, or U.S. Pat. No. 5,717,821, filed by the inventors of the present invention. Tone components separated by this method and non-tone components are quantized using different numbers of bits by processing by the tone component encoder 32 and the non-tone component encoder 33, which will be described below.

The tone component encoder 32 and the non-tone component encoder 33 each encode the input signals. The tone component encoder 32 quantizes the tone components using a large number of quantization bits, that is, with high quantization accuracy. The non-tone component encoder 33 quantizes the non-tone components using a small number of quantization bits, that is, with low quantization accuracy.

Although it is necessary to add, to each of the tone components, new information including information indicating the position of the tone component and information indicating the width of a frequency extracted as the tone component, the spectrum signals of the non-tone components are quantized using a small number of bits. In particular, when the acoustic waveform signal input to the encoder 4 is a signal in which energy is concentrated in a specific spectrum, the above-described method enables efficient coding at a high compression ratio without degrading the auditory quality of the signal.

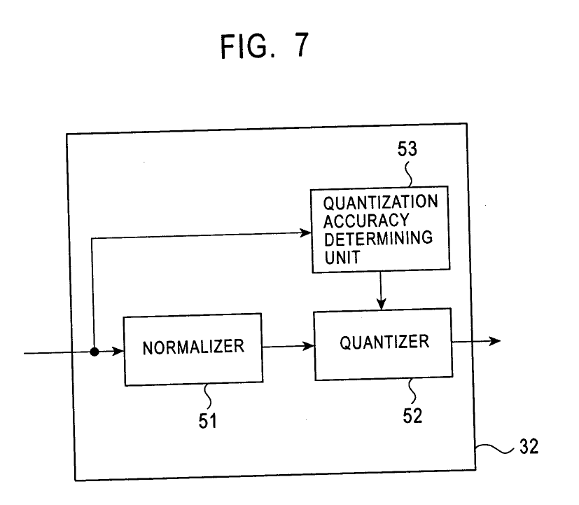

FIG. 7 is a block diagram of the detailed configuration of the tone component encoder 32 shown in FIG. 5.

A normalizer 51 receives an input of spectrum signals of a tone component in each quantization unit, normalizes the spectrum signals, and outputs the normalized spectrum signals to a quantizer 52. A quantization accuracy determining unit 53 refers to the input quantization unit, computes quantization accuracy, and outputs the computation result to the quantizer 52. Since the input quantization unit includes a tone component, the quantization accuracy determining unit 53 computes the quantization accuracy so that the quantization accuracy becomes high. The quantizer 52 quantizes the normalization result input from the normalizer 51 using the quantization accuracy determined by the quantization accuracy determining unit 53 and generates a code. In addition to the generated code, the quantizer 52 outputs coding information including the normalization coefficient information and the quantization accuracy information.

In addition to the tone components, the tone component encoder 32 encodes the tone-component position information, which is input along with the tone components, and outputs the encoded position information along with the tone components.

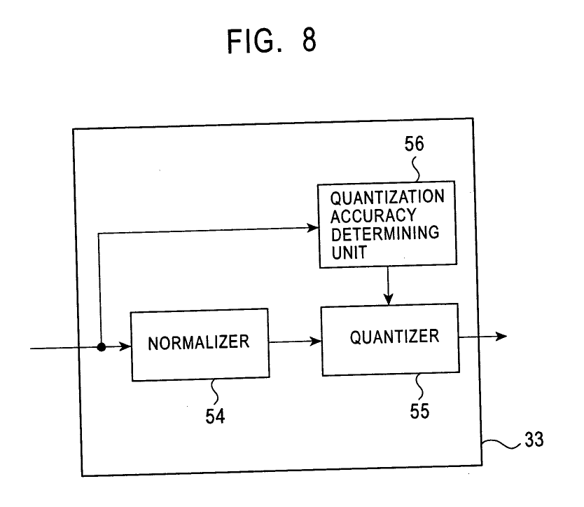

FIG. 8 is a block diagram of the detailed configuration of the non-tone component encoder 33 shown in FIG. 5.

A normalizer 54 receives spectrum signals of a non-tone component in each quantization unit, normalizes the spectrum signals, and outputs the normalized spectrum signals to a quantizer 55. A quantization accuracy determining unit 56 refers to the input quantization unit, computes quantization accuracy, and outputs the computation result to the quantizer 55. Since the input quantization unit includes a non-tone component, the quantization accuracy determining unit 56 computes the quantization accuracy so that the quantization accuracy becomes low. The quantizer 55 quantizes the normalization result input from the normalizer 54 using the quantization accuracy determined by the quantization accuracy determining unit 56 and generates a code. In addition to the generated code, the quantizer 52 outputs coding information including the normalization coefficient information and the quantization accuracy information.

The coding efficiency may be further increased from that of the above-described coding method. For example, of the spectrum signals quantized by variable-length coding, a relatively short code length is assigned to a more frequent spectrum signal, and a relatively long code length is assigned to a less frequent spectrum signal. Accordingly, the coding efficiency is further increased.

From codes of the signal frequency components output by the signal component encoder 12, the code string generator 13 shown in FIG. 2 generates, for example, a code string that can be recorded on a recording medium or that can be transmitted to another information processing apparatus via a data transmission line, that is, a code string consisting of a plurality of frames, and outputs the code string to the trial data generator 14. The code string generated by the code string generator 13 is audio data that can be played with high sound quality by a normal decoder.

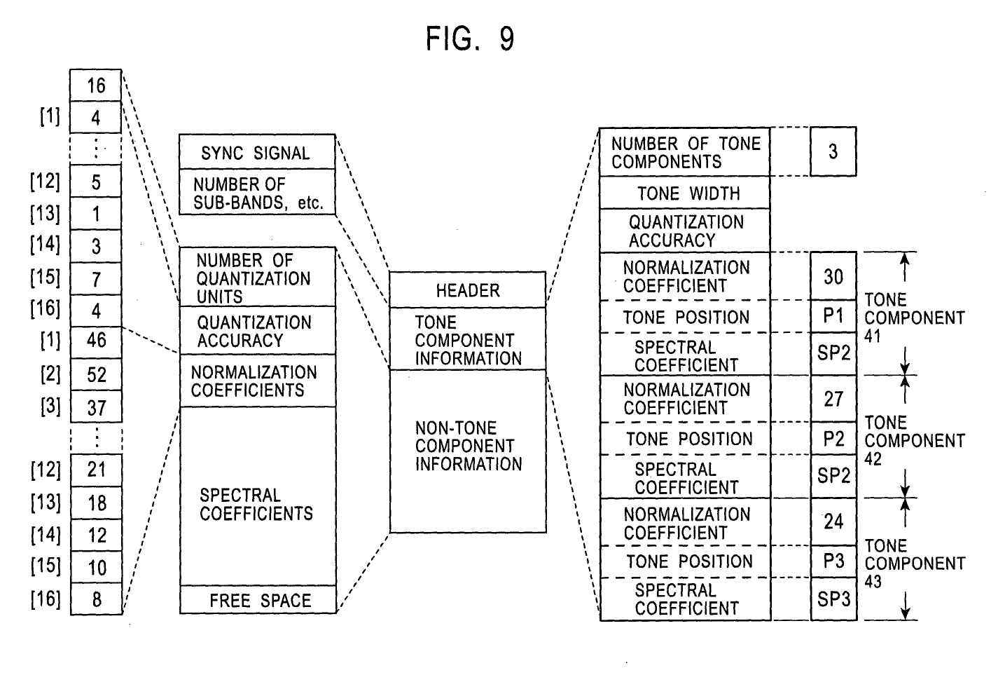

FIG. 9 shows an example of the format of a frame of the audio data, which is generated by the code string generator 13 and which can be played with high sound quality.

At the head of each frame, a fixed-length header including a sync signal is arranged. The header includes the number of sub-bands of the sub-band filter 21 of the transform unit 11, which has been illustrated in FIG. 3, a flag indicating whether or not trial time information (described below) is included in this frame, and the like.

In each frame, subsequent to the header, tone component information on the separated tone components is recorded. The tone component information includes the number of tone components (three in this case), tone width, and quantization accuracy information on the quantization of the tone components by the tone component encoder 32, which is illustrated in FIG. 7. Subsequently, data for tone components 41 to 43 are recorded, each of which includes a normalization coefficient, tone position, and a spectral coefficient. In this case, for example, the tone component 41 has the normalization coefficient 30, the tone position P1, and the spectral coefficient SP1; the tone component 42 has the normalization coefficient 27, the tone position P2, and the spectral coefficient SP2; and the tone component 43 has the normalization coefficient 24, the tone position P3, and the spectral coefficient SP3.

Subsequent to the tone component information, non-tone component information is written. The non-tone component information includes the number of quantization units (sixteen in this case), quantization accuracy information on the quantization of the non-tone components in each of the sixteen quantization units by the non-tone component encoder 33, which is illustrated in FIG. 8, normalization coefficient information, and spectral coefficient information. The quantization accuracy information includes a value in each of the quantization units, ranging from 4 in quantization unit [1] at the lowest frequency to 4 in quantization unit [16] at the highest frequency. The normalization coefficient information includes a value in each of the quantization units, ranging from 46 in quantization unit [1] at the lowest frequency to 8 in quantization unit [16] at the highest frequency.

As the normalization coefficient information, values in proportion to the power level of the spectrum signals (in dB) are used. When the length of the content frame is fixed, free space may be provided after the spectral coefficient information.

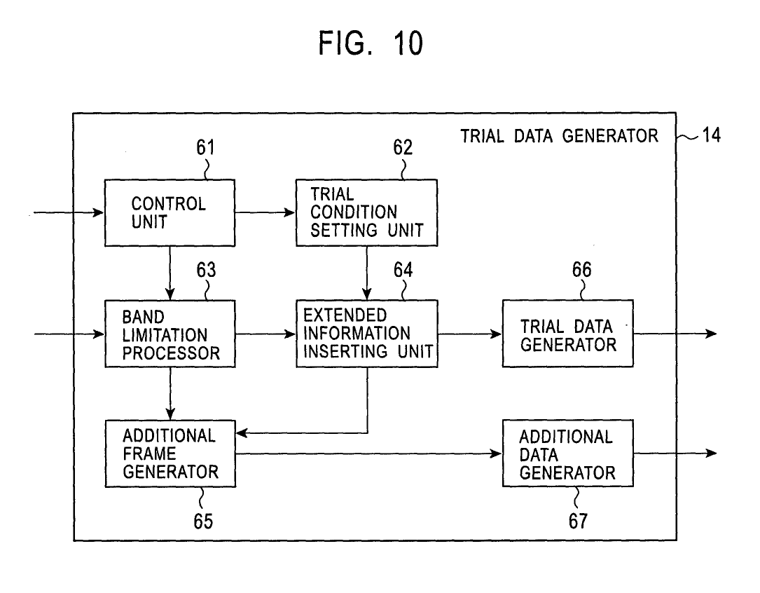

FIG. 10 is a block diagram of the detailed configuration of the trial data generator 14 shown in FIG. 2.

A control unit 61 controls a trial condition setting unit 62 and a band limitation processor 63 on the basis of setting data input from an external operation input unit (not shown). The setting data includes trial time information, a trial-permitted area(s), the trial frequency band of each of the trial-permitted area(s) (frequency band within which listening on a trial basis is permitted), and the like. Each trial-permitted area is, of the trial data, a portion that can be played with low quality without using the additional data.

Upon playback of the trial data by the data player 5, a trial area(s) is selected from among the trial-permitted areas so that the play time is within the trial time indicated by the trial time information, and the trial area(s) is played with low sound quality (in a band-limited manner). Although a plurality of trial areas may be selected from among the trial-permitted area(s), the total play time must be within the trial time. The trial frequency band of each trial-permitted area is a frequency band in which low-quality playback is permitted. For example, of the spectral data illustrated in FIG. 6, only some of the quantization units are specified to allow playback within frequency bands in a predetermined range. As a result, the quality of the playback sound is reduced.

In this case, the total play time when playing the trial data is limited on the basis of the trial time information. Instead of the trial time information, the total play time when playing the trial data may be limited on the basis of the maximum of sum of data length of pieces of trial-permitted data.

Under the control of the control unit 61, the trial condition setting unit 62 determines, in each frame illustrated in FIG. 9, whether or not the input frame is within the trial-permitted area, determines a frame(s) into which the trial time information is inserted, and outputs the trial time information and information on the frame(s) into which the trial time information is inserted to an extended information inserting unit 64.

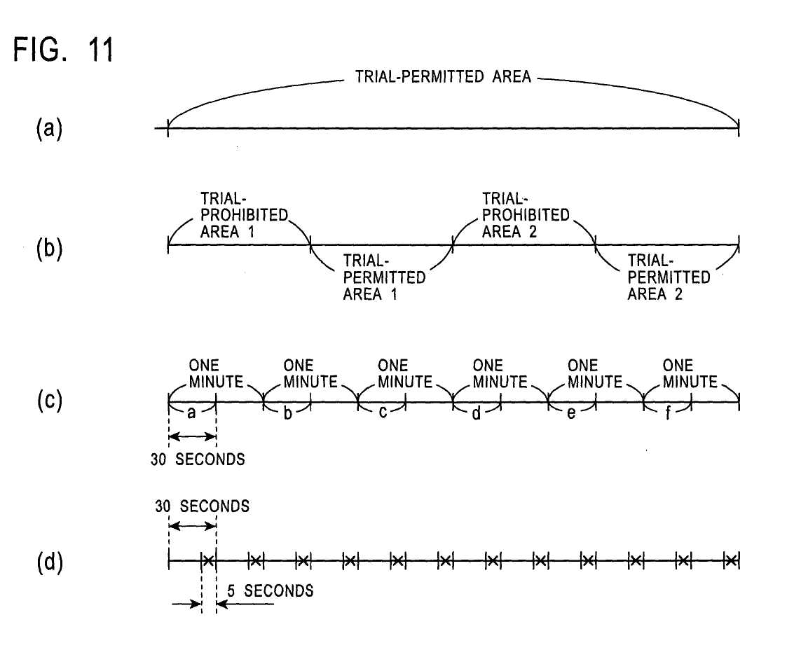

Using FIG. 11, the trial-permitted area(s) will now be described.

For example, as shown in FIG. 11(a), the overall trial data may serve as a trial-permitted area. When playing or recording data, a trial area is selected from the overall trial data so that the play time (or recording time) is within the trial time. As shown in FIG. 11(b), portions of the trial data may serve as trial-permitted areas, and the remaining portions may serve as trial-prohibited areas. When playing or recording data, portions within the trial time are selected from trial-permitted areas 1 and 2. FIG. 11(b) shows two trial-permitted areas, that is, trial-permitted areas 1 and 2, and two trial-prohibited areas, that is, trial-prohibited areas 1 and 2. The number of trial-permitted areas and the number of trial-prohibited areas may be one or may be three or greater.

As shown in FIG. 11(b), when the trial data includes trial-permitted areas and trial-prohibited areas, trial data may include trial-permitted-range information. When playing or recording data, the data player 5 or the data recorder 7 may refer to the trial-permitted-range information and determine the trial start position.

As shown in FIG. 11(c), the trial data may be divided into blocks of unit time (in FIG. 11(c), six-minute trial data is divided into blocks of one minute). The first half (first 30 seconds) of the blocks may serve as trial-permitted areas a to f, and the remaining portions may serve as trial-prohibited areas. For example, when the trial time is set to two minutes, upon playing or recording data, four areas are selected from among the trial-permitted areas a to f and the selected areas are played or recorded.

As shown in FIG. 11(c), when a thirty-second trial-permitted area is set every minute in the trial data, the trial data may include trial-start-position accuracy information (in this case, information indicating that the trial start position is set at intervals of one minute). When playing or recording data, the data player 5 or the data recorder 7 may refer to the trial-start-position accuracy information and determine the trial start position.

As shown in FIG. 11(d), the trial data may be divided into blocks of unit time (in FIG. 11(d), six-minute trial data is divided into blocks of thirty seconds). Portions of the blocks (in FIG. 11(d), the last five seconds of the blocks) may serve as trial-prohibited areas, and the remaining portions may serve as trial-permitted areas. For example, if the trial time is set to one minute, when playing or recording data, the data player 5 or the data recorder 7 may specify only one start position of the trial area and start playing or recording data. As a result, the played or recorded sound may be interrupted at two or three points.

The trial time information is recorded in a frame(s) in, for example, one of the following patterns: (1) all frames; (2) all frames in a trial-permitted area(s); (3) frames at predetermined intervals in a trial-permitted area(s); (4) the first frame of the first trial-permitted area; and (5) the first frames of all trial-permitted areas.

The trial condition setting unit 62 selects one of the above five patterns, determines a frame(s) into which the trial time information is inserted, and outputs the trial time information and information on the frame(s) into which the trial time information is inserted to the extended information inserting unit 64.

Under the control of the control unit 61, the band limitation processor 63 generates, in each frame illustrated in FIG. 9, data in which the trial frequency band is limited on the basis of whether or not the input frame is within a trial-permitted area. Information on the trial frequency band in the trial-permitted area is input from the control unit 61.

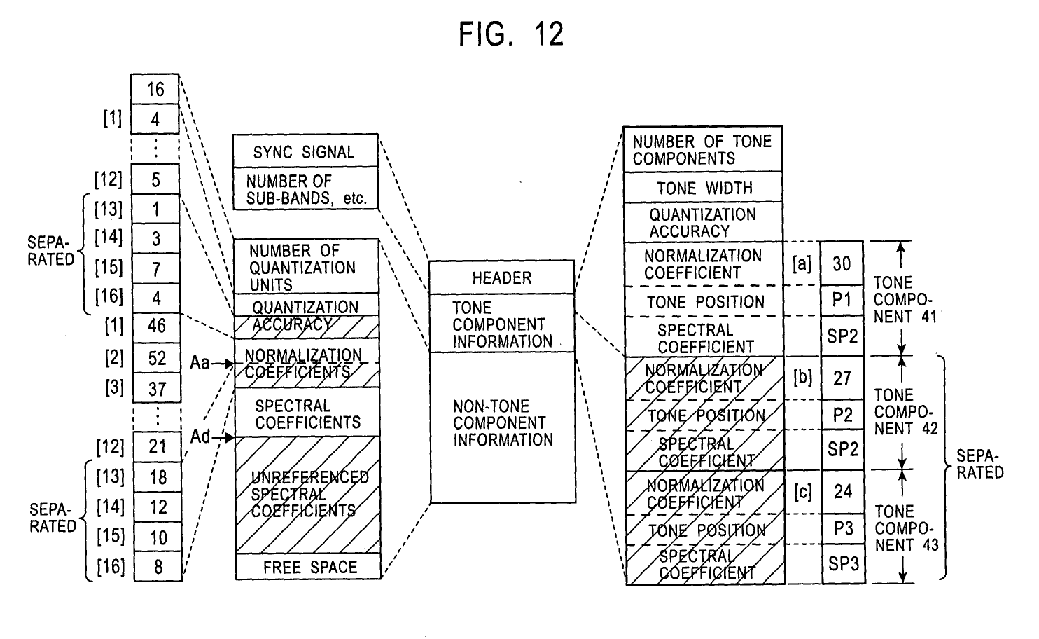

For example, in a case in which quantization units [1] to [12] are designated as the trial frequency band of a trial-permitted area, when the input frame is a frame in the trial-permitted area, as shown in FIG. 12, the band limitation processor 63 separates the values of the quantization accuracy information and the normalization coefficient information of quantization units [13] to [16] higher than the trial frequency band from the input frame, outputs the separated values or information to an additional frame generator 65, and minimizes values that are written in the input frame and that are associated with the separated information. Effective values are written as the spectral coefficient information corresponding to quantization units [13] to [16]. Since the corresponding normalization coefficients are minimized, during playback, the corresponding spectra are not exactly zero though substantially equal to zero in the perceptual sense. The spectral coefficient information on the high frequency side of the position denoted as Ad in FIG. 12 is synonymous with information that is not referred to during playback.

As in the non-tone components, the band limitation processor 63 separates, from the input frame, the values of the quantization accuracy information and the normalization coefficients out of the trial frequency band of the tone components, outputs the separated values or information to the additional frame generator 65, and minimizes values that are written in the input frame and that are associated with the separated information.

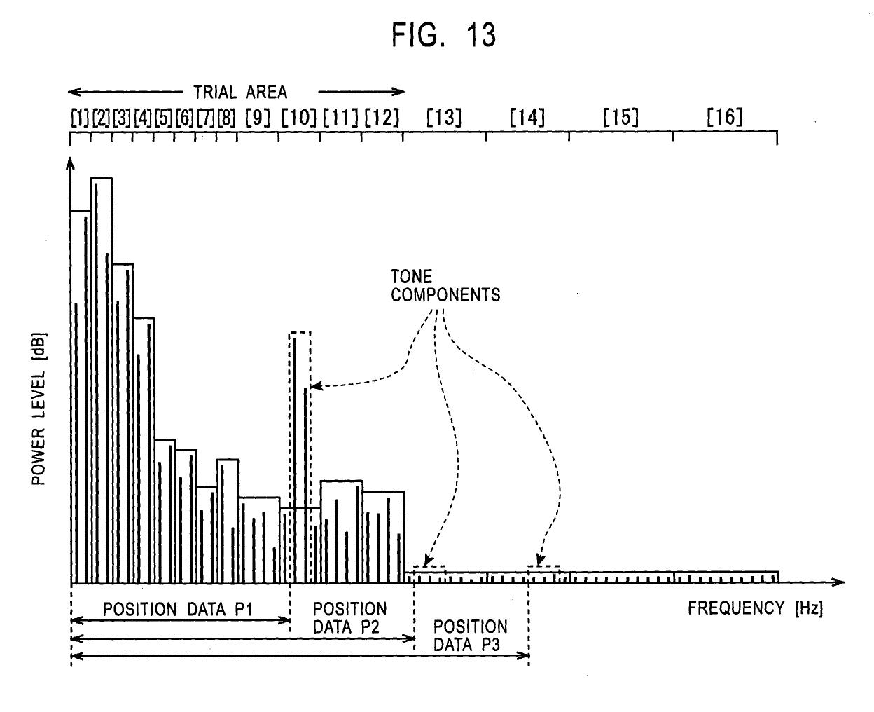

FIG. 13 shows spectrum signals upon playback of the trial data from which part of the data out of the trial frequency band is separated, which is illustrated in FIG. 12. Since the normalization coefficient information in quantization units [13] to [16] is separated, the corresponding spectrum signals are minimized. For two tone components included in quantization units [13] to [16], similarly the corresponding spectrum signals are minimized. In other words, when the trial data is decoded and played, only narrow-band spectrum signals are played in the trial-permitted area.

Accordingly, upon playback of the trial-permitted area(s) of the trial data, only narrow-band data is played. Compared with the original data illustrated in FIG. 9, low-quality data is played.

The band limitation processor 63 changes values of all pieces of normalization coefficient information in quantization units [1] to [16] of a frame corresponding to a portion of a trial-prohibited area to minimum (in this case, it is assumed that the minimum is zero). Thus, the corresponding spectral coefficients become substantially zero, and playback is not performed. The band limitation processor 63 inserts control information indicating that a trial is prohibited into part of the unreferenced spectral coefficient information. The band limitation processor 63 separates, from the input frame, values of all pieces of normalization coefficient information in quantization units [1] to [16] of the frame corresponding to the portion of the trial-prohibited area of the tone portions and the non-tone portions. Accordingly, the band limitation processor 63 transforms data in the trial-prohibited frame (protected area) so that no sound is generated even when the data in the trial-prohibited frame is played or recorded. Data including the true normalization coefficient information when all the values of the normalization coefficient information are changed to minimum, the spectral coefficient information replaced with the control information indicating that a trial is prohibited, and/or the separated normalization coefficient information is output to the additional frame generator 65 and thus included in an additional frame.

Of the trial data generated by separating part of the data out of the trial frequency band, which is illustrated in FIGS. 12 and 13, the trial area can be played with low sound quality by the data player 5 of the client 3-1 (described below) and by the data player 6 (known data player) of the client 3-2 and can be recorded with low sound quality by the data recorder 7 of the client 3-3 (described below) and by the data recorder 8 (known data recorder) of the client 3-4.

With the processing by the extended information inserting unit 64, the trial data generator 14 generates, as the trial data, data that cannot be played by the data player 6 (known data player) of the client 3-2, that cannot be recorded by the data recorder 8 (known data recorder) of the client 3-4, that can be played by the data player 5 of the client 3-2, and that can be recorded by the data recorder 7 of the client 3-3, which will be described later.

With the processing by the band limitation processor 63, the extended information inserting unit 64 receives an input of a frame in the trial-permitted area, from which normalization coefficients out of the trial frequency band are removed, which is illustrated in FIG. 12, and changes the number of tone components of the tone component information and the number of quantization units of the non-tone component information to minimum (zero in this case). Also, the extended information inserting unit 64 changes the number of tone components of the tone component information and the number of quantization units of the non-tone component information to minimum (zero in this case), thus reducing a recording area for the non-tone component information. As a result, the extended information inserting unit 64 arranges an extended area in the frame. The extended area is a data area that is not referred to during playback by the data player 6 (known data player) of the client 3-2 or recording by the data recorder 8 (known data recorder) of the client 3-4.

When quantization units [1] to [12] serve as the trial frequency band, the extended information inserting unit 64 rearranges, in the extended area, the number of tone components within the trial frequency band (tone component 41) (value 1), the normalization coefficient information (value 30), the tone position information (P1), and the spectral coefficient information (SP2), the number of quantization units of the non-tone components within the trial area (value 12), quantization accuracy information and normalization coefficient information of the non-tone components in quantization units [1] to [12], and spectral coefficient information in all quantization units.

From the trial data generated as above, no sound (even band-limited) can be played by the data player 6 (known data player) of the client 3-2 or can be recorded by the data recorder 8 (known data recorder) of the client 3-4. In contrast, from the generated trial data, band-limited sound can be played by the data player 5 of the client 3-1 and can be recorded by the data recorder 7 of the client 3-3, which will be described later.

As has been illustrated in FIG. 12, when the values of the normalization coefficient information in quantization units [13] to [16] higher than the trial frequency band are separated, the spectral coefficient information on the high frequency side of the position denoted by Ad in FIG. 12, which is associated with quantization units [13] to [16], is synonymous with not being referred to. In this range, arbitrary control information may be written.

On the basis of information input from the trial condition setting unit 62, the extended information inserting unit 64 inserts the trial time information into an area in which the spectral coefficients higher than the trial frequency band are recorded and outputs the resultant information to a trial data generator 66. The extended information inserting unit 64 turns on or off the flag indicating that the trial time information is included (trial time information flag) in the header of each frame so that the data player 5 or the data recorder 7 can detect the frame(s) including the trial time information. As has been described earlier, the trial time information may be written in all frames or in some of the frames. The extended information inserting unit 64 outputs the true spectral coefficient information corresponding to a portion in which the trial time information is written and, where necessary, information indicating the position at which the trial time information is inserted to the additional frame generator 65.

Also, the extended information inserting unit 64 may write random dummy data or the like at a position at which no trial time information is written, which is within the range of the spectral coefficient information on the high frequency side of the position denoted by Ad in FIG. 12. In this case, the extended information inserting unit 64 outputs the true spectral coefficient information corresponding to a portion in which the dummy data is written and, where necessary, information indicating the position at which the dummy data is inserted to the additional frame generator 65.

In the above description, the trial time information and the dummy data are inserted at positions corresponding to the spectral coefficient information that is not referred to during playback of the trial data. The trial time information and the dummy data may be inserted at any position other than that associated with the spectral coefficient information as long as the position is in a portion that is not referred to during playback of the trial data.

The extended information inserting unit 64 generates a trial frame using the trial time information and dummy data for replacement, in which the data length of the decoded trial data is prevented from becoming longer than the data length of the decoded original data.

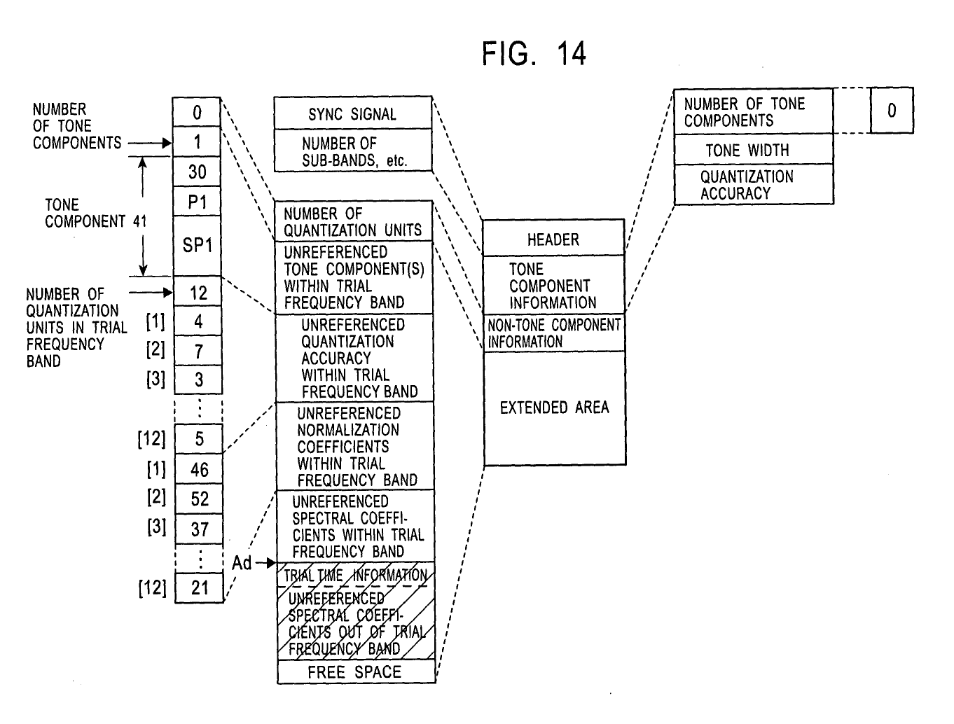

FIG. 14 shows the format of a frame including the trial time information.

When quantization units [1] to [12] are selected to serve as a trial area, normalization coefficient information, tone position information, and spectral coefficient information of tone components corresponding to quantization units [13] to [16] and quantization accuracy information and normalization coefficient information of non-tone components corresponding to quantization units [13] to [16] are separated from the generated trial frame. The number of tone components of the tone component information and the number of quantization units of the non-tone component information are changed to zero. Unseparated information in the trial area is moved and arranged in the extended area not referred to during playback or recording. The trial time information is written in part of an area in which spectral coefficient information out of the trial area (on the high frequency side of the position denoted by Ad in FIG. 14). The spectral coefficient information replaced with the trial time information is data recorded in a data area that is not used for the actual playback or recording even when, upon playback or recording of the trial data, the number of tone components and the number of quantization units are recovered on the basis of the trial frequency band and the information in the extended area is rearranged in an area that can be referred to.

FIG. 14 illustrates the frame in which part of the spectral coefficient information out of the trial area is replaced with the trial time information. Alternatively, part of the spectral coefficient information out of the trial area may be replaced not only with the trial time information but also with dummy data. In a frame in which the trial time information is not written, part of the spectral coefficient information out of the trial area may be replaced only with the dummy data.

Particularly when the spectral coefficient information is variable-length coded and the variable length codes are arranged sequentially from low frequency to high frequency in an area in which the spectral coefficient information is written, writing the trial time information (or dummy data) in an area including the unreferenced spectral coefficient information results in losing some of the variable-length codes at intermediate frequencies. Higher-frequency data including the missing portion cannot be decoded at all. In other words, the spectral coefficient information, which is included in the trial data and which is related with the original data, is difficult to recover without using additional data. Security of the trial data is thus enhanced.

When part of the data, such as the normalization coefficients, is missing, or when part of the data, such as the spectral coefficients, is replaced with different data, true data corresponding to the missing data or the replaced data is very difficult to estimate compared with decryption of an encrypted key of relatively short key length. When the trial data is altered without authorization, the sound quality is further degraded. It thus becomes very difficult for a user not allowed to listen to a trial version of the original data to estimate the original data on the basis of the trial data. The rights of the creator and distributor of the content data are secured more tightly.

Even if true data corresponding to the missing or replaced data in the trial data is estimated, unlike a case in which an encrypted algorithm is decrypted, the incurred damage does not spread to other pieces of content. Security is thus higher than a case where content data decrypted using a specific algorithm is distributed as trial data.

Accordingly, true normalization coefficient information, tone position information, and spectral coefficient information of the tone components separated by the band limitation processor 63; true quantization accuracy information and normalization coefficient information of the non-tone components separated by the band limitation processor 63; and true spectral coefficient information of the non-tone components replaced by the extended information inserting unit 64 are supplied to the additional frame generator 65 described below and written in an additional frame.

When the extended area has free space, the extended information inserting unit 64 may arrange, even if tone components and non-tone components are out of the trial frequency band, values of normalization coefficient information, tone position information, and spectral coefficient information of these tone components and values of quantization accuracy information and normalization coefficients of these non-tone components in the extended area. In this case, the band limitation processor 63 outputs these pieces of data, which are out of the trial frequency band and which are to be written in the extended area, to the extended information inserting unit 64, not to the additional frame generator 65. The extended information inserting unit 64 writes the data out of the trial frequency band, which is supplied by the band limitation processor 63, in the extended area.

Difficulty of unauthorizedly estimating the original data from the trial data without using additional data, that is, the security of the trial data, differs between a case in which the normalization coefficient information out of the trial frequency band is written in the extended area of the trial frame and a case in which the quantization accuracy information out of the trial frequency band is written in the extended area of the trial frame. For example, in a case where the original data is generated by a bit allocation algorithm involving computation of the quantization accuracy information on the basis of the normalization coefficient information, when the normalization coefficient information out of the trial frequency band is written in the extended area, there is a slight risk that the true quantization accuracy information may be estimated on the basis of the normalization coefficient information in the extended area.

In contrast, when the quantization accuracy information out of the trial frequency band is written in the extended area of the trial frame, the normalization coefficient information is difficult to estimate from the quantization accuracy information. Therefore, the security of the trial data is high. The risk of the original data being estimated unauthorizedly is reduced further by not writing both the normalization coefficient information and the quantization accuracy information out of the trial frequency band in the extended area of the trial frame. Alternatively, the normalization coefficient information and the quantization accuracy information may be selectively written in the extended area depending on the content frame of the trial data.

The additional frame generator 65 receives an input of information on the tone components and the non-tone components out of the trial frequency band, which are band-limited and separated by the band limitation processor 63, true values of all pieces of normalization coefficient information in quantization units [1] to [16] of the frame corresponding to the portion of the trial-prohibited area, and true spectral coefficient information of the non-tone components replaced with the trial time information or dummy data by the extended information inserting unit 64 and generates an additional frame included in additional data for recovering the original data, which is to be purchased by a user who has listened to the trial data and wants to play or record the piece of music with high sound quality.

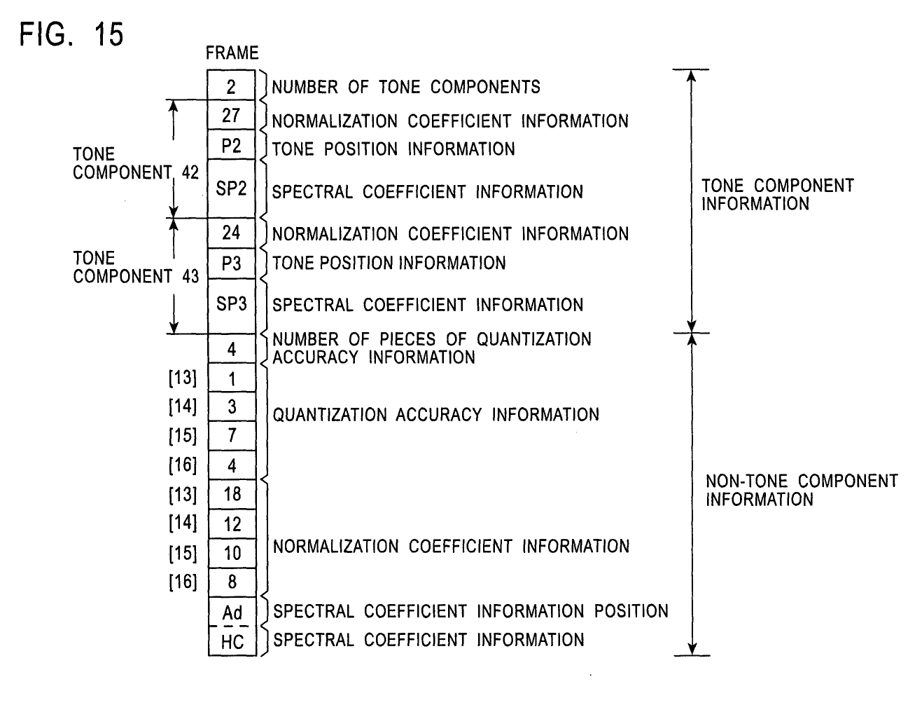

FIG. 15 shows the format of an additional frame corresponding to a trial-permitted band. When quantization units [1] to [12] are selected to serve as the trial frequency band, the additional frame generator 65 receives, from the band limitation processor 63, a supply of normalization coefficient information, tone position information, and spectral coefficient information of tone components (tone components 42 and 43 in this case) and quantization accuracy information and normalization coefficient information of non-tone portions, which correspond to four quantization units [13] to [16], in each frame of the trial data. The additional frame generator 65 receives, from the extended information inserting unit 64, an input of part of the unreferenced spectral coefficient information replaced with the trial time information and the position of this spectral coefficient information (position Ad in FIG. 14). On the basis of these pieces of information, the additional frame generator 65 computes the number of tone components and the number of pieces of quantization accuracy information, which are to be included in the additional frame, and generates the additional frame shown in FIG. 15.

The additional frame includes additional information corresponding to the tone components and additional information corresponding to the non-tone components. Referring to FIG. 15, the number of separated tone components (two components are separated in this case) and normalization coefficient information, tone position information, and spectral coefficient information of these tone components are written as the additional information corresponding to the tone components. The number of normalization coefficients of the separated non-tone components (four components are separated in this case), quantization accuracy information and normalization coefficient information of these non-tone components, true spectral coefficient information replaced with the trial time information, and the position thereof (Ad) are written as the additional information corresponding to the non-tone components.

Referring to FIG. 15, the position information of the true spectral coefficient information replaced with the trial time information is included in the generated additional frame. If this portion of the spectral coefficient information replaced with the trial time information is the head portion of the unreferenced spectral coefficient information in the trial frame, the position of the true spectral coefficient information replaced with the trial time information may be estimated on the basis of the number of quantization units in the trial area even when the position information is not included in the additional frame. In other words, when the position of the spectral coefficient information replaced with the trial time information differs from the head of the unreferenced spectral coefficient information, the position information of the true spectral coefficient information replaced with the trial time information must be written in the additional frame.

By writing part of the information included in the additional frame in the extended area, the volume of the additional data including the additional frame is reduced. For example, when a user records the additional data on a recording medium, such as a magneto-optical disk, using so-called MMK, the processing time is reduced. When a user downloads the additional data from the server 2 via the network 1, the communication time is reduced. In these cases, a portion corresponding to the data written in the extended area is not included in the additional frame.

Although not shown in the drawing, true values of all pieces of normalization coefficient information in quantization units [1] to [16] are written in the additional frame associated with the frame corresponding to the portion of the trial-prohibited area.

The trial data generator 66 generates a header of the trial data, adds the generated header to an encoded frame sequence of the input trial data to generate the trial data, and outputs the trial data. The header of the trial data includes, for example, information including the content ID for distinguishing content, content title, or coding information.

An additional data generator 67 generates a header of the additional data, adds the generated header of the additional data to an encoded frame sequence of the input additional data to generate the additional data, and outputs the additional data. The header of the additional data includes information including the content ID for discriminating content and associating the additional data with the trial data, the play time of the content (original data), and, where necessary, coding information.

Since the trial frequency band is limited to reduce the playback quality of the trial data, and the band-limited playback data and the trial time information are written in an area that is not referred to during playback by the known data player 6 or recording by the known data recorder 8, the trial data can be played or recorded by the data player 5 or the data recorder 7 having a function of rearranging the position of the band-limited trial data.

With the processing described below, the data player 5 or the data recorder 7 having a function of rearranging the position of the band-limited trial data can recover the original data using the trial data and the additional data, which are generated by the trial data generator 14.

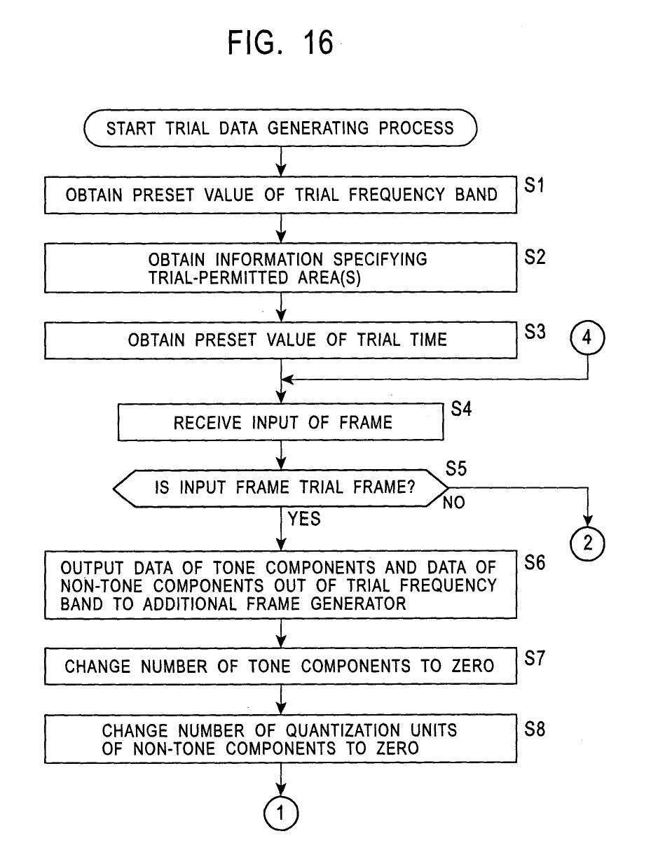

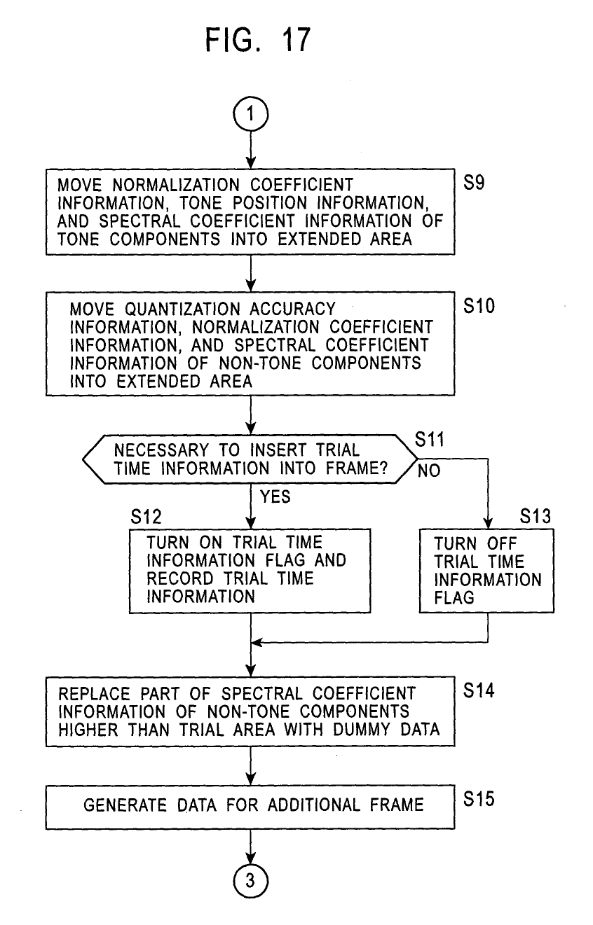

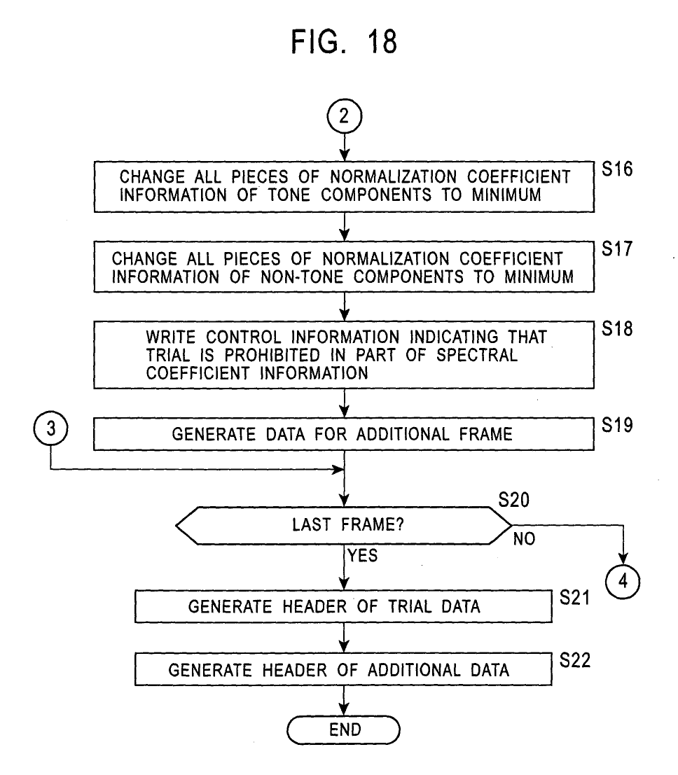

Referring to the flowcharts of FIGS. 16 to 18, a trial data generating process will now be described.

In step Si, the control unit 61 of the trial data generator 14 obtains a preset value of the trial frequency band of a trial-permitted area in trial data, which is input from an operation input unit (not shown) or the like. As has been illustrated in FIG. 13, quantization units [1] to [12] are selected to serve as the trial frequency band. The control unit 61 supplies the preset value of the trial frequency band to the band limitation processor 63.

In step S2, the control unit 61 obtains information specifying a trial-permitted area(s) in the trial data, which is input from the operation input unit (not shown) or the like. As has been illustrated in FIG. 11, the entire trial data or part(s) thereof is set to serve as the trial-permitted area(s). The control unit 61 supplies the information specifying the trial-permitted area(s) to the trial condition setting unit 62 and the band limitation processor 63.

In step S3, the control unit 61 obtains a preset value of the trial time, which is the maximum period for which the trial data is played (or recorded) by a single trial, which is input from the operation input unit (not shown) or the like. The control unit 61 supplies information on the preset trial time to the trial condition setting unit 62.

In step S4, the band limitation processor 63 receives an input of one of the frames included in a frame sequence corresponding to the original data, that is, a frame that can be played with high sound quality, which has been illustrated in FIG. 9.

In step S5, the trial condition setting unit 62 and the band limitation processor 63 determine whether or not the input frame is a trial frame (frame included in the trial-permitted area) on the basis of the information supplied by the control unit 61.

When it is determined in step S5 that the input frame is a trial frame, in step S6, the band limitation processor 63 separates a portion out of the frequency band specified by the preset value of the trial frequency band, which is supplied by the control unit 61, from data of tone components and non-tone components, as shown in FIG. 12. The band limitation processor 63 outputs the separated data to the additional frame generator 65 and the remaining unseparated data to the extended information inserting unit 64. When part of the data out of the trial frequency band is to be written in the extended area, the band limitation processor 63 outputs part of the separated data to the extended information inserting unit 64 and the remaining part of the data to the additional frame generator 65.

In step S7, the extended information inserting unit 64 changes the number of tone components, which is included in the tone component information in the input frame, to zero. In step S8, the extended information inserting unit 64 changes the number of quantization units to zero.

In step S9, the extended information inserting unit 64 moves normalization coefficient information, tone position information, and spectral coefficient information of the tone components into the extended area.

In step S10, the extended information inserting unit 64 moves quantization accuracy information, normalization coefficient information, and spectral coefficient information of the non-tone components into the extended area.

In step S11, the extended information inserting unit 64 determines whether or not the frame being processed at present is a frame into which the trial time information should be inserted. As has been described above, the method of setting a frame(s) into which the trial time information is inserted has various patterns, such as all frames of the trial data, all frames in a trial-permitted area(s), frames in a trial-permitted area(s) at predetermined intervals, the first frame of the first trial-permitted area, and the first frames in all trial-permitted areas.

When it is determined in step S11 that the current frame is a frame into which the trial time information should be inserted, in step S12, the extended information inserting unit 64 turns on the trial time information flag included in the header of the frame, replaces the spectral coefficient information on the high frequency side of the trial area (e.g., on the high frequency side of the position denoted by Ad in FIG. 14) with the trial time information, and outputs the values of the spectral coefficient information replaced with the trial time information to the additional frame generator 65.

When it is determined in step S11 that the current frame is not a frame into which the trial time information should be inserted, in step S13, the extended information inserting unit 64 turns off the trial time information flag included in the header of the frame.

After the processing in step S12 or step S13, in step S14, the extended information inserting unit 64 replaces part of the spectral coefficient information on the high frequency side of the trial area with dummy data and outputs the values of the spectral coefficient information replaced with the dummy data to the additional frame generator 65. All pieces of the dummy data replacing the spectral coefficient information may be 0's or may appropriately include 1's and 0's.

In step S15, the additional frame generator 65 generates, on the basis of the signals input from the band limitation processor 63 and the extended information inserting unit 64, data for an additional frame corresponding to the frame in the trial-permitted area, which has been illustrated in FIG. 15, of additional data to be purchased by a user who has listened to the trial data and wants to listen to the piece of music with high sound quality. The process proceeds to step S20.

When it is determined in step S5 that the input frame is not a trial frame, in step S16, the band limitation processor 63 changes all pieces of normalization coefficient information of the tone components to minimum (i.e., zero). In step S17, the band limitation processor 63 changes all pieces of normalization coefficient information of the non-tone components to minimum (i.e., zero). In step S18, the band limitation processor 63 writes control information indicating that a trial is prohibited in part of the unreferenced spectral coefficient information. The extended information inserting unit 64 outputs a frame corresponding to the generated trial-prohibited area to the trial data generator 66 and outputs the true normalization coefficient information, which has been changed to minimum in steps S16 and S17, and the true spectral coefficient information, which has been replaced with the control information indicating that a trial is prohibited in step S18, to the additional frame generator 65.

Similarly, when the spectral coefficient information has been variable-length coded, the spectral coefficient information is replaced with such control information in which the bit length of the decoded control information becomes shorter than the bit length of the decoded true spectral coefficient information. In addition to the control information, the spectral coefficient information may be replaced with dummy data.

Instead of changing all pieces of normalization coefficient information of the tone components and the non-tone components to minimum (i.e., zero), values of normalization coefficient information in quantization units [1] to [16] (or values of tone position information, quantization accuracy information, and spectral coefficient information of the tone portions) may be separated from the input frame. Accordingly, even when data in the trial-prohibited frame is played or recorded, no sound is generated.

In step S19, the additional frame generator 65 generates, on the basis of the signal input from the band limitation processor 63, data for an additional frame corresponding to the frame in the trial-prohibited area, which is part of the additional data to be purchased by the user who has listened to the trial data and wants to listen to the piece of music with high sound quality.

After the processing in step S15 or S19, in step S20, the trial data generator 66 determines whether or not the processed frame is the last frame. When it is determined in step S20 that the processed frame is not the last frame, the process returns to step S4, and the processing from step S4 onward is repeated.

When it is determined in step S20 that the processed frame is the last frame, in step S21, the trial data generator 66 generates a header of the trial data, adds the header to a trial frame sequence to generate the trial data, and outputs the trial data.

In step S22, the additional data generator 67 uses the input information to generate a header of the additional data, adds the header to an additional frame sequence to generate the additional data, and outputs the additional data. The process is thus terminated.

With the process described with reference to the flowcharts of FIGS. 16 to 18, the trial data in which only the trial-permitted area(s) can be played with low quality and the additional data for recovering the original data from the trial data are generated.

In the above description, the trial time information is inserted into the trial data. Alternatively, instead of inserting the trial time information into the trial data, the trial time information may be stored in advance in the data player 5 or the data recorder 7 for playing or recording the trial data. Using the stored trial time information, frames included in a trial area may be selected from among the frames included in the trial-permitted area(s).

As has been described earlier, when encoding the input signal, the signal component encoder 12 of the encoder 4 separates the input signal into tone components and non-tone components and separately encodes the tone components and the non-tone components. Alternatively, instead of using the signal component encoder 12, the non-tone component encoder 33 shown in FIG. 8 may be used to encode the input signal without separating the input signal into tone components and non-tone components.

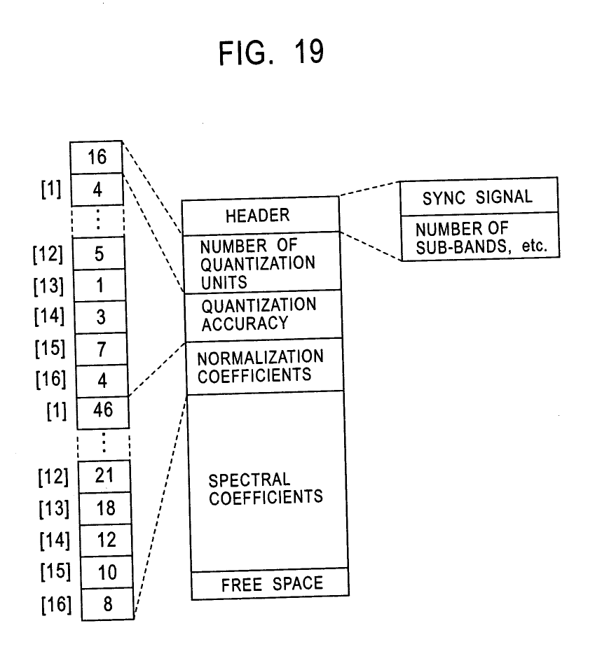

FIG. 19 shows an example of the format of a high-quality original data frame generated by the code string generator 13 when the input signal is not separated into tone components and non-tone components.

At the head of the original data frame, as in the case described with reference to FIG. 9, a fixed-length header including a sync signal is arranged. The header includes, in addition to the sync signal, the number of sub-bands of the sub-band filter 21 of the transform unit 11, which is illustrated in FIG. 3, the trial time information flag, and the like. Subsequent to the header, the number of quantization units (sixteen in this case), quantization accuracy information on the quantization by the non-tone component encoder 33, and normalization coefficient information and spectral coefficient information in each of the sixteen quantization units are recorded.

The quantization accuracy information includes a value in each of the quantization units, ranging from 4 in quantization unit [1] at the lowest frequency to 4 in quantization unit [16] at the highest frequency. The normalization coefficient information includes a value in each of the quantization units, ranging from 46 in quantization unit [1] at the lowest frequency to 8 in quantization unit [16] at the highest frequency. When the length of the content frame is fixed, free space may be provided after the spectral coefficient information.

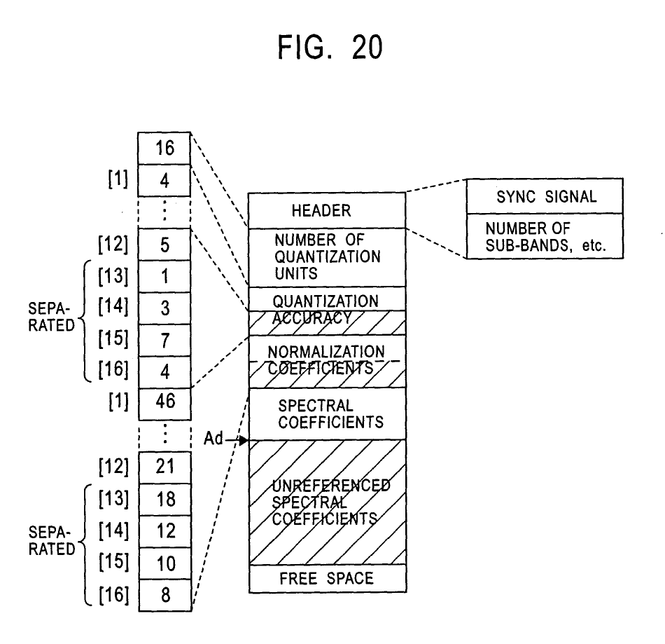

For example, when quantization units [1] to [12] are specified to serve as a trial frequency band of a trial-permitted portion, as in the case illustrated in FIG. 12, referring to FIG. 20, values of quantization accuracy information and normalization coefficient information in quantization units [13] to [16] higher than the trial frequency band are separated from the original data frame illustrated in FIG. 19. Although effective values are written in part of spectral coefficient information corresponding to quantization units [13] to [16], the corresponding spectra are minimized during playback.

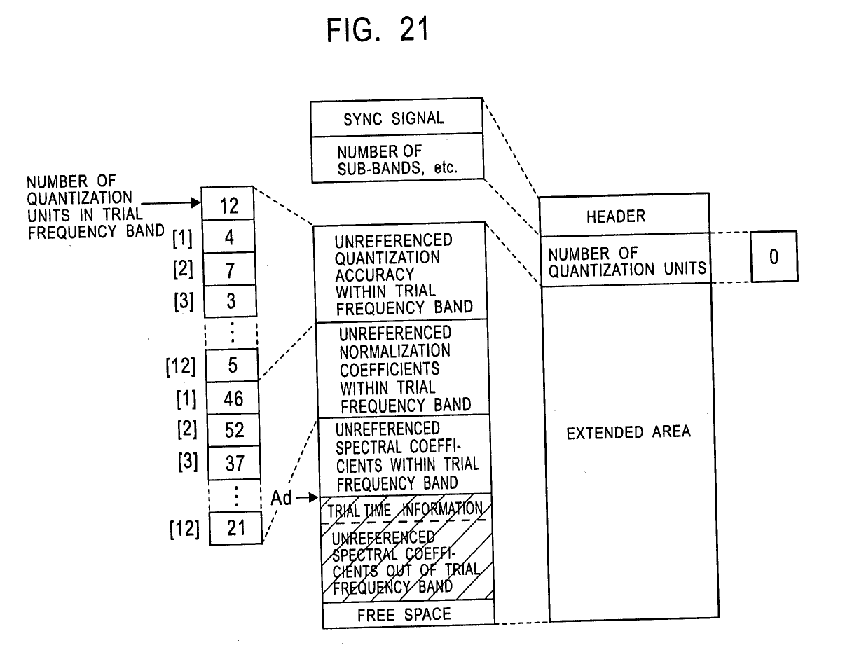

FIG. 21 shows the format of audio data in the trial portion, which is generated by the trial data generator 14 upon reception of an input of the original data frame illustrated in FIG. 19. Referring to FIG. 21, the number of quantization units is replaced with zero, and, where necessary, the trial time information is written in some of the unreferenced spectral coefficients. Also, dummy data may be written in some of the unreferenced spectral coefficients.

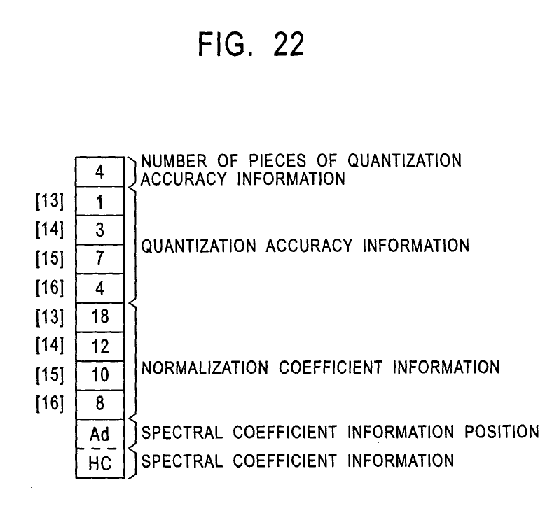

FIG. 22 shows an additional frame generated by the additional frame generator 65 of the trial data generator 14 upon reception of an input of the original data frame illustrated in FIG. 19. The additional frame includes the number of pieces of quantization accuracy information in the separated quantization units (four components are separated in this case), the separated quantization accuracy information, the separated normalization coefficient information, the true spectral coefficient information replaced with the trial time information or dummy data, and the position information thereof.

As has been illustrated in FIGS. 19 to 22, even when tone components are not separated, with the similar processing, trial data in which audio corresponding to the frame(s) within the trial time is played with low quality and additional data for recovering the original data from the trial data are generated.

Even when tone components are not separated, instead of inserting the trial time information into the trial data, the trial time information may be stored in advance in the data player 5 or the data recorder 7 for playing or recording the trial data.

The trial data generated in this manner is distributed to the user's client 3-1 or client 3-3 via the network 1, such as the Internet, or may be recorded onto the user's various recording media and distributed using MMK, which is the client 3-3 in a store or the like. When the user plays the trial data and likes the sound played, the user pays a predetermined fee to a distributor of the content data (proprietor managing the server 2) to obtain the additional data. Using the trial data and the additional data, the user recovers the original data and decodes and plays the original data or records the original data onto a recording medium.

A process of decoding and outputting or playing the trial data or of decoding and outputting or playing the original data from the trial data and the additional frame will now be described.

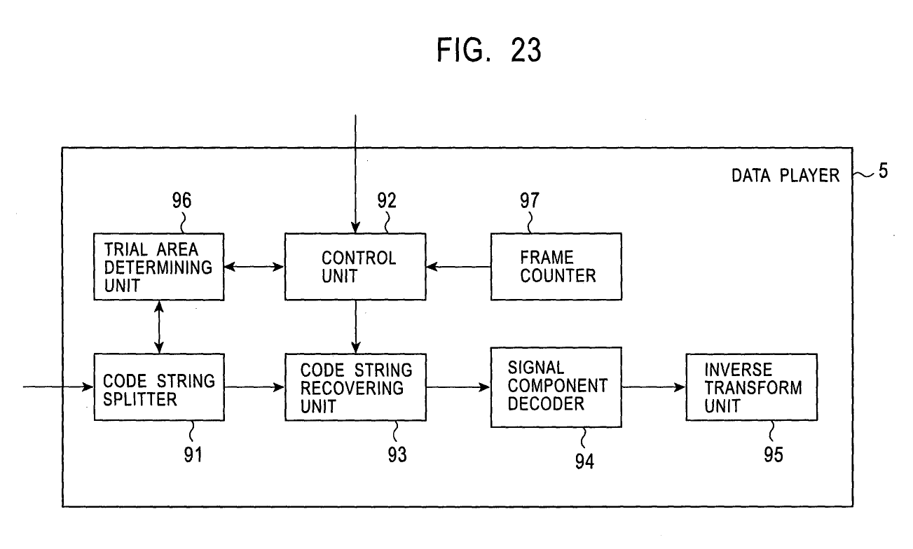

FIG. 23 is a block diagram of the configuration of the data player 5.

A code string splitter 91 receives an input of encoded trial data, splits a code string into codes of signal components, and outputs the codes to a code string recovering unit 93. The code string splitter 91 refers to the split codes for the trial time information flag and determines whether or not the trial time information is written in this frame. If the trial time information is written, the trial time information is extracted and output to a trial area determining unit 96.

Instead of writing the trial time information in the trial frame, the trial time information may be stored in advance in a storage unit (not shown) included in a control unit 92, or the value of the trial time information may be programmed in advance in a program to be executed by the control unit 92. Accordingly, the trial time information may be read from the control unit 92 into the trial area determining unit 96.

In order to perform trial playback instead of high-quality playback, the trial area determining unit 96 selects trial frames from among trial-permitted frames on the basis of the trial time information input from the code string splitter 91 or read from the control unit 92 and determines a trial area(s). One or multiple trial areas may be selected as long as the total play time is within the trial time. The trial start position may be determined at random by generating, for example, a random number so that different trial areas may be played every time trial playback is done.

For example, as shown in FIG. 11(a), when the overall trial data serves as a trial-permitted area, the trial area determining unit 96 randomly selects the trial start position between the beginning of the trial data and a position which is the trial time before the end of the trial data, selects frames that start from the selected trial start position and that are within the trial time as trial frames, and notifies the control unit 92 of the trial frames.

As shown in FIG. 11(b), when the trial data includes trial-permitted areas and trial-prohibited areas, the trial area determining unit 96 randomly selects the trial start position between the beginning of the trial-permitted area 1 or the trial-permitted area 2 and a position which is the trial time prior to the end of the trial-permitted area 1 or the trial-permitted area 2, selects frames that start from the selected trial start position and that are within the trial time as trial frames, and notifies the control unit 92 of the trial frames.

As shown in FIG. 11(c), in a case in which a thirty-second trial-permitted area is set every minute, when the trial time is one minute, the trial area determining unit 96 randomly selects two trial-permitted areas from among the trial-permitted areas a to f, selects frames included in the two selected trial-permitted areas as trial frames, and notifies the control unit 92 of the trial frames.

As shown in FIG. 11(c), when a thirty-second trial-permitted area is set every minute in the trial data, the trial data may include trial-start-position accuracy information (in this case, information indicating that the trial start position is set at intervals of one minute). The trial area determining unit 96 may refer to the trial-start-position accuracy information and determine two trial start positions.

As shown in FIG. 11(d), in a case in which a five-second trial-prohibited area is set every thirty seconds and the remaining portions are set to serve as trial-permitted areas, for example, when the trial time is one minute, the trial area determining unit 96 randomly selects the trial start position between the beginning of the first trial-permitted area to a position which is a period of “the trial time+10 seconds” before the end of the last trial-permitted area, and selects frames that start from the selected trial start position and whose playback time excluding the trial-prohibited areas is within the trial time as trial frames, and notifies the control unit 92 of the trial frames.

When there are multiple trial areas or a trial area contains a trial-prohibited area(s) (for example, when trial-permitted areas are set as shown in FIG. 11(d)), in order to prevent unnatural playback at the boundary between trial areas, fade-in and fade-out may be performed to achieve natural and continuous playback.

The control unit 92 receives a user's operation from an operation input unit (not shown) and controls the processing by the code string recovering unit 93 on the basis of information indicating whether to play the input data with high sound quality. If necessary, the control unit 92 receives an input of additional data and supplies the additional data to the code string recovering unit 93. The control unit 92 may store in advance the trial time information enabling the trial area determining unit 96 to determine a trial area(s) or may program the trial time information enabling the trial area determining unit 96 to determine a trial area(s) in a program to be executed by the control unit 92.

In order to perform trial playback, the control unit 92 controls the code string recovering unit 93 on the basis of information that is supplied by the trial area determining unit 96 and that indicates a trial area(s) (trial frames) to rearrange data arranged in the extended area of each trial frame at playable positions. On the basis of this information, which is supplied by the trial area determining unit 96 and which indicates a trial area(s) (trial frames), the control unit 92 activates a frame counter 97 to count the number of frames played. When the count by the frame counter 97 reaches a number corresponding to the trial time, the trial playback processing is terminated.

In order to perform high-quality playback, if necessary, the control unit 92 supplies data necessary for high-quality playback, such as normalization coefficient information, tone position information, and spectral coefficient information of tone components, and quantization accuracy information, normalization coefficient information, and spectral coefficient information of non-tone components, to the code string recovering unit 93 and recovers the original data.

In order to perform trial playback of the input trial data, under the control of the control unit 92, the code string recovering unit 93 rearranges data within the trial frequency band, which is part of the data in the extended area of each input encoded frame, at positions to which a signal component decoder 94 can refer to. Also, the code string recovering unit 93 recovers the number of tone components, which is included in the tone component information, and the number of quantization units, which is included in the non-tone component information, on the basis of the trial frequency band and outputs the recovered numbers to the signal component decoder 94. In order to recover the original data from the input trial data and play the original data, under the control of the control unit 92, the code string recovering unit 93 recovers the encoded frames of the original data from the encoded frames of the trial data on the basis of various pieces of information supplied by the control unit 92, such as normalization coefficient information, tone position information, and spectral coefficient information of the tone components, and quantization accuracy information, normalization coefficient information, and spectral coefficient information of the non-tone components, and outputs the recovered encoded frames of the original data to the signal component decoder 94.

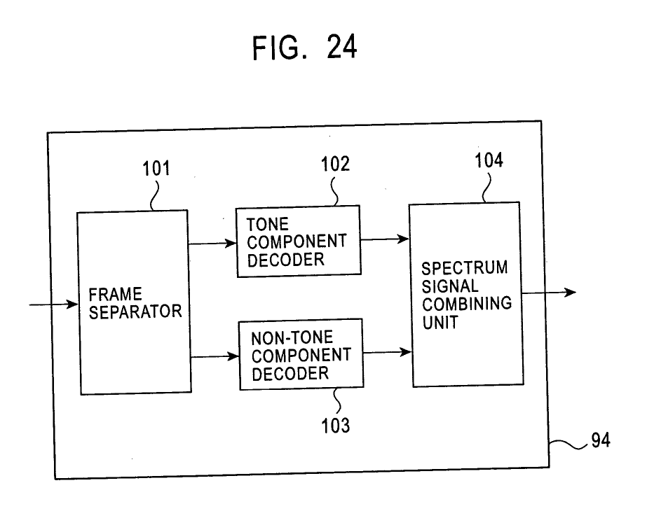

The signal component decoder 94 decodes the encoded frames of the input trial data or the original data. FIG. 24 is a block diagram of the detailed configuration of the signal component decoder 94 for decoding each input encoded frame, which is generated by being separated into tone components and non-tone components and then being encoded.

A frame separator 101 receives an input of an encoded frame, such as that shown in FIG. 14, separates the encoded frame into tone components and non-tone components, and outputs the tone components to a tone component decoder 102 and the non-tone components to a non-tone component decoder 103.

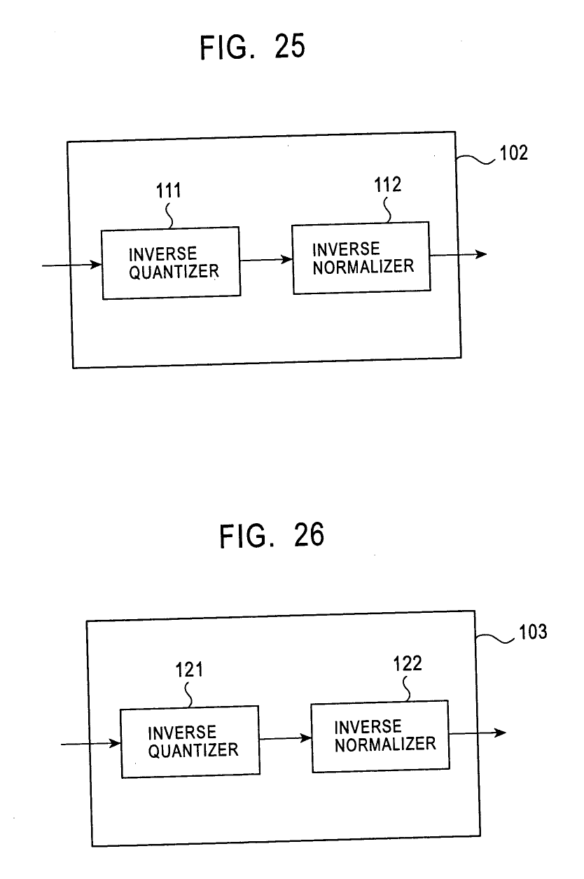

FIG. 25 is a block diagram of the detailed configuration of the tone component decoder 102. An inverse quantizer 111 performs inverse quantization of the input encoded data and outputs the inverse-quantized data to an inverse normalizer 112. The inverse normalizer 112 inverse-normalizes the input data. In other words, the data is decoded by the inverse quantizer 111 and the inverse normalizer 112 to output spectrum signals of the tone portions.

FIG. 26 is a block diagram of the detailed configuration of the non-tone component decoder 103. An inverse quantizer 121 performs inverse quantization of the input encoded data and outputs the inverse-quantized data to an inverse normalizer 122. The inverse normalizer 122 inverse-normalizes the input data. In other words, the data is decoded by the inverse quantizer 121 and the inverse normalizer 122 to output spectrum signals of the non-tone portions.

A spectrum signal combining unit 104 receives an input of the spectrum signals output by the tone component decoder 102 and the non-tone component decoder 103, combines these signals to generate spectrum signals, which are illustrated in FIG. 6 showing the original data or in FIG. 13 showing the trial data, and outputs the generated spectrum signals to an inverse transform unit 95.

When the encoded data is not generated by being separated into tone components and non-tone components and then being encoded, the frame separator 101 may be omitted, and decoding may be performed by only one of the tone component decoder 102 and the non-tone component decoder 103.

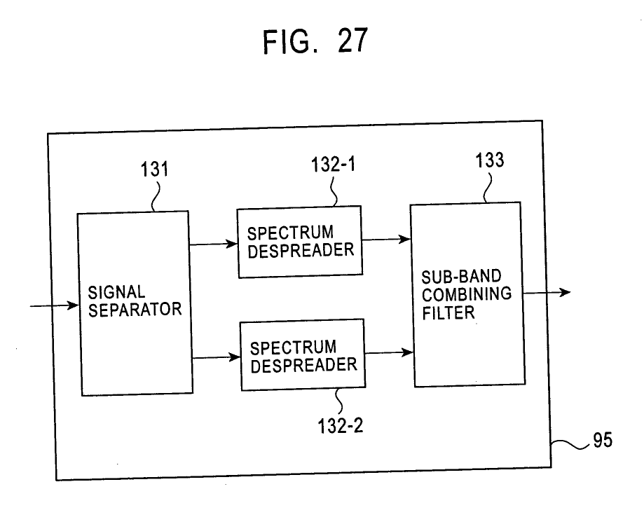

FIG. 27 is a block diagram of the detailed configuration of the inverse transform unit 95.

A signal separator 131 separates the signals on the basis of the number of sub-bands, which is written in the header of the input frame. It is assumed that the number of sub-bands is two. The signal separator 131 separates the input spectrum signals into two sets of signals, which are supplied to spectrum despreaders 132-1 and 132-2, respectively.

The spectrum despreaders 132-1 and 132-2 each despread the input spectrum signals and output the despread signals in the corresponding sub-band to a sub-band combining filter 133. The sub-band combining filter 133 combines the input sub-band signals and outputs the combined signal.

The signal output by the sub-band combining filter 133 (e.g., audio PCM signal) is converted by a digital-to-analog (D/A) converter (not shown) into analog data, and the analog data is output as sound from a speaker (not shown). The signal output by the sub-band combining filter 133 may be output to another apparatus via a network or the like.

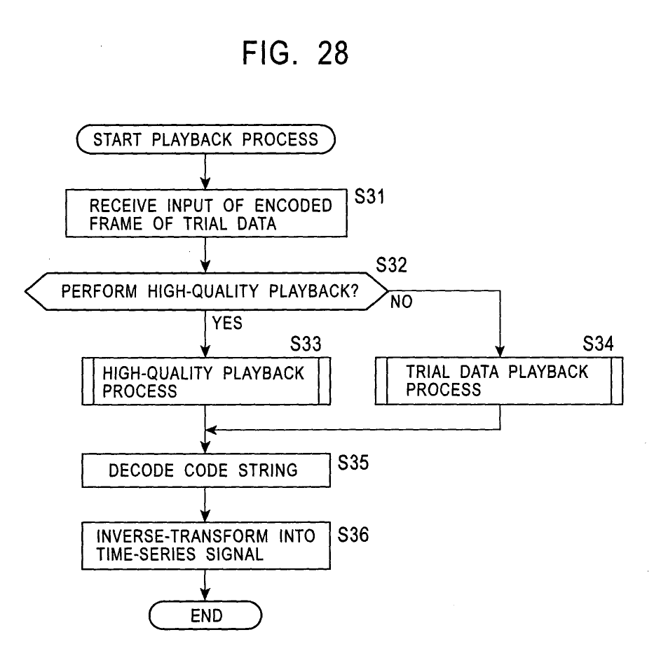

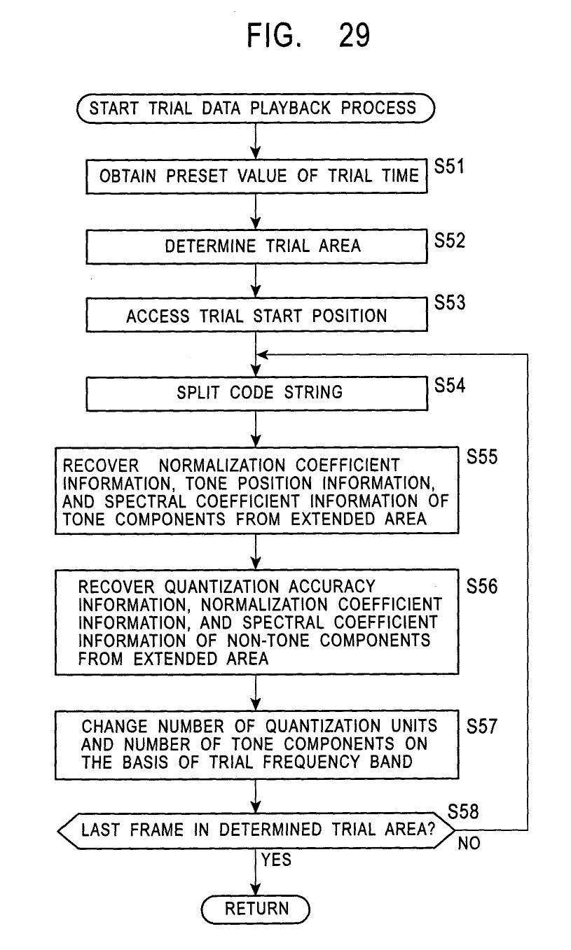

Referring to the flowchart of FIG. 28, a playback process executed by the data player 5 shown in FIG. 23 will now be described.

In step S31, the code string splitter 91 receives an input of an encoded frame of trial data.

In step S32, the code string recovering unit 93 determines whether to perform high-quality playback, that is, whether to perform a process of recovering and playing the original data, on the basis of a signal input from the control unit 92.

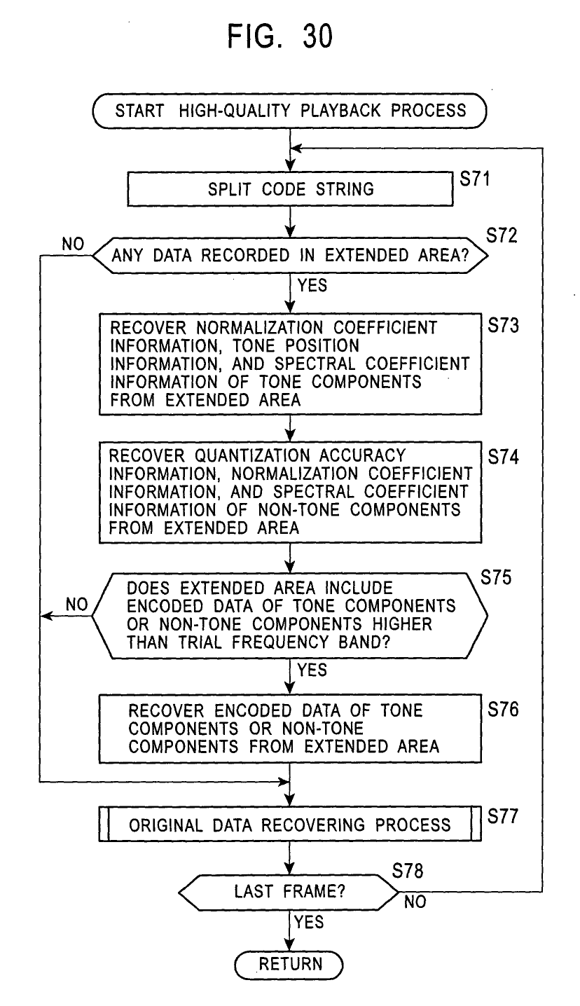

When it is determined in step S32 to perform high-quality playback, in step S33, a high-quality playback process, which will be described later with reference to the flowchart of FIG. 30, is performed.

When it is determined in step S32 not to perform high-quality playback, the input frame is to be played as trial data. In step S34, a trial data playback process, which will be described later with reference to the flowchart of FIG. 29, is performed.

After the processing in step S33 or step S34, in step S35, the signal component decoder 94 separates an input code string into tone components and non-tone components, decodes the tone components and the non-tone components by inverse quantization and inverse normalization to synthesize spectrum signals, and outputs the signals to the inverse transform unit 95.

In step S36, the inverse transform unit 95 divides, where necessary, the input spectrum signals into sub-bands, despreads the sub-band signals, combines the sub-band signals, and inverse-transforms the combined signal into a time-series signal. The process is terminated.

The time-series signal generated by inverse transformation by the inverse transform unit 95 may be converted by a D/A converter (not shown) into analog data, and the analog data may be output as sound from a speaker (not shown). Alternatively, the time-series signal may be output to another apparatus or the like via a network (not shown).

Referring to the flowchart of FIG. 29, the trial data playback process, which is performed in step S34 in FIG. 28, will now be described.

In step S51, the trial area determining unit 96 obtains a preset value of a trial time, which is extracted from the trial data by the code string splitter 91 or stored in advance in the control unit 92.

In step S52, the trial area determining unit 96 determines from a trial-permitted area(s) a trial start position on the basis of the preset value of the trial time, which has been obtained in step S51, and determines a trial area(s) including trial frames to be played for a play time that is within the trial time. The trial start position may be selected at random from a predetermined area based on the trial-permitted area(s) and the trial time by generating, for example, a random number. Alternatively, a trial may be started at a predetermined position. The trial area determining unit 96 outputs the determined trial start position and the trial area(s) to the control unit 92 and the code string splitter 91.

In step S53, the code string splitter 91 accesses the trial start position on the basis of the trial start position and the trial area(s), which are supplied by the trial area determining unit 96. In step S54, the code string splitter 91 receives an input of the frames selected as the trial area(s), splits a code string into codes, and outputs the codes to the code string recovering unit 93.

In step S55, the code string recovering unit 93 under the control of the control unit 92 reads, from the extended area of each of the supplied frames, normalization coefficient information, tone position information, and spectral coefficient information of tone components within the trial frequency band, which are written in the extended area, and recovers, that is, rearranges, these pieces of information at positions that can be referred to by the signal component decoder 94 when decoding.

In step S56, the code string recovering unit 93 under the control of the control unit 92 reads, from the extended area of the supplied frame, quantization accuracy information, normalization coefficient information, and spectral coefficient information of non-tone components within the trial frequency band, which are written in the extended area, and recovers, that is, rearranges, these pieces of information at positions that can be referred to by the signal component decoder 94 when decoding.

In step S57, the code string recovering unit 93 under the control of the control unit 92 changes the number of quantization units and the number of tone components, which have been set to minimum (i.e., zero), on the basis of the trial frequency bandwidth. For example, as has been illustrated in FIGS. 12 and 13, when quantization units [1] to [12] serve as the trial frequency band and only the tone component 41 is within the trial frequency band, the number of quantization units is recovered from zero to twelve, and the number of tone components is recovered from zero to one. The recovered numbers are output to the signal component decoder 94. The signal component decoder 94 decodes data in the input frame and outputs the decoded data to the inverse transform unit 95. The inverse transform unit 95 inverse-transforms the input data and plays/outputs the inverse-transformed data.

In step S58, the control unit 92 determines whether or not the processed frame is the last frame of the determined trial area.

When it is determined in step S58 that the processed frame is not the last frame, the process returns to step S54, and the processing from step S54 onward is repeated. When it is determined in step S58 that the processed frame is the last frame, the process proceeds to step S35 in FIG. 28.

If necessary, processing, such as fade-in or fade-out, is performed to prevent unnatural playback at the start or end portion of the trial data or the boundary between multiple trial areas.

Referring to the flowchart of FIG. 30, the high-quality playback process, which is performed in step S33 in FIG. 2,8, will now be described.

In step S71, the code string splitter 91 splits an input code string into codes and outputs the codes to the code string recovering unit 93.

In step S72, the code string recovering unit 93 determines whether or not data is recorded in the extended area of the input frame, that is, whether the input frame is a trial-permitted frame or a trial-prohibited frame.

When it is determined in step S72 that data is recorded in the extended area of the input frame, that is, the input frame is a trial-permitted frame, in steps S73 and S74, the processing similar to that in steps S55 and S56 in FIG. 29 is performed. In other words, as in the case of trial playback, data within the trial frequency band in the extended area is rearranged in a playable area.

In step S75, the code string recovering unit 93 determines whether or not the extended area includes encoded data of tone components or non-tone components higher than the trial frequency band.

When it is determined in step S75 that the extended area includes encoded data of tone components or non-tone components higher than the trial frequency band, in step S76, the code string recovering unit 93 reads, from the extended area, the encoded data of the tone components or the non-tone components and recovers, that is, rearranges, the encoded data at positions that can be referred to by the signal component decoder 94 when decoding.

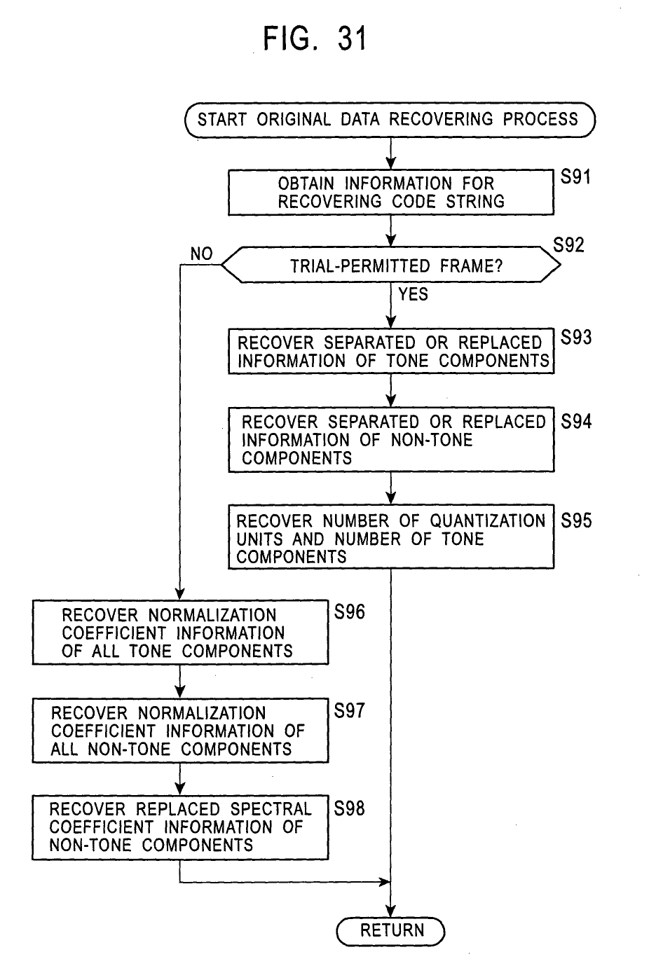

When it is determined in step S72 that the extended area of the input frame includes no data, that is, when it is determined that the input frame is a trial-prohibited frame, when it is determined in step S75 that the extended area includes no encoded data of tone components or non-tone components higher than the trial frequency band, or subsequent to the processing in step S76, in step S77, a original data recovering process, which will be described later with reference to the flowchart of FIG. 31, is performed.

In step S78, the control unit 92 determines whether or not the processed frame is the last frame.

When it is determined in step S78 that the processed frame is not the last frame, the process returns to step S71, and the processing from step S71 onward is repeated. When it is determined in step S78 that the processed frame is the last frame, the signal component decoder 94 decodes data in the input frame and outputs the decoded data to the inverse transform unit 95. The inverse transform unit 95 inverse-transforms the input data and plays and outputs the inverse-transformed data. The process proceeds to step S35 in FIG. 28.

With reference to the flowchart of FIG. 31, the original data recovering process, which is performed in step S77 in FIG. 30, will now be described.

In step S91, the code string recovering unit 93 obtains additional data, which is information for recovering the code string, from the control unit 92.

When the original data has been separated into tone components and non-tone components, an additional frame in the additional data includes, as shown in FIG. 15, corresponding to the tone components, the number of separated tone components (two components are separated in this case) and normalization coefficient information, tone position information, and spectral coefficient information of these tone components; and, corresponding to the non-tone components, the number of normalization coefficients of the separated non-tone components (four components are separated in this case), quantization accuracy information and normalization coefficient information of these non-tone components, and the true spectral coefficient information of the non-tone components replaced with the trial time information and the position thereof (Ad).

When the original data has not been separated into tone-components and non-tone components, as shown in FIG. 22, the additional frame includes the number of pieces of quantization accuracy information in the separated quantization units (four components are separated in this case), the separated quantization accuracy information, the separated normalization coefficient information, the true spectral coefficient information replaced with the trial time information or dummy data, and the position information thereof.

In step S92, the code string recovering unit 93 receives an input of a frame split by the code string splitter 91 and determines whether or not the input frame is a trial-permitted frame.

When it is determined in step S92 that the input frame is a trial-permitted frame, in step S93, the code string recovering unit 93 uses the data included in the additional frame illustrated in FIG. 15 or FIG. 22 and recovers the separated or replaced information of the tone components of the trial data.

In step S94, the code string recovering unit 93 uses the data included in the additional frame illustrated in FIG. 15 or FIG. 22 and recovers the separated or replaced information of the non-tone components of the trial data.

In step S95, the code string recovering unit 93 recovers the number of quantization units and the number of tone components to values corresponding to the-original data. For example, when the original data includes the frame illustrated in FIG. 9, the number of quantization units is recovered to 16, and the number of tone components is recovered to 3. The code string recovering unit 93 supplies the recovered data to the signal component decoder 94. The process proceeds to step S78 in FIG. 30.

When it is determined in step S92 that the input frame is not a trial-permitted frame, that is, the input frame is a trial-prohibited frame (protected frame), in step S96, the code string recovering unit 93 uses the true values of normalization coefficient information in all quantization units of the tone components included in the additional frame corresponding to the trial-prohibited frame and recovers the normalization coefficient information of all tone components, which have been replaced with zero in the trial frame of the trial data.

In step S97, the code string recovering unit 93 uses the true values of normalization coefficient information in all quantization units of the non-tone components included in the additional frame corresponding to the trial-prohibited frame and recovers the normalization coefficient information of all non-tone components, which have been replaced with zero in the trial frame of the trial data.

In step S98, the code string recovering unit 93 uses the true values of spectral coefficient information in all quantization units of the non-tone components included in the additional frame corresponding to the trial-prohibited frame, recovers the spectral coefficient information of the non-tone components, which have been replaced with the control information indicating that a trial is prohibited or with the dummy data in the trial frame of the trial data, and supplies the recovered data to the signal component decoder 94. The process returns to step S78 in FIG. 30.

With the processes shown by the flowcharts of FIGS. 30 and 31, the original data is recovered from the trial data and the additional data.

In the processes illustrated in FIGS. 28 to 31, the trial data generated by being encoded into tone components and non-tone components and then being encoded or the original data recovered from this trial data is played. Similarly, even trial data that has not been separated into tone components and non-tone components or the original data recovered from such trial data may be decoded and played.

When the original data is to be recovered using the additional data including the additional frame illustrated in FIG. 15, that is, when all pieces of information higher than the trial frequency band (information that is separated when the original data is generated) are included in the additional data, the original data is recovered on the basis of the data included in the additional frame. When part or the entirety of the information higher than the trial frequency band is written in the extended area of the trial frame (area that is not referred to during the trial playback), the code string recovering unit 93 uses, in addition to the data included in the additional frame, this information, which is included in the extended area of the trial frame and which is higher than the trial frequency band, to recover the replaced normalization coefficient information.

The trial data decoded or the original data recovered and decoded by the processes illustrated in FIGS. 23 to 31 may be played by a speaker (not shown) or, for example, may be output to another apparatus via a network or the like.

A process of recording the trial data onto a recording medium or a process of recovering the original data from the trial data and the additional frame and recording the original data onto a recording medium will now be described.

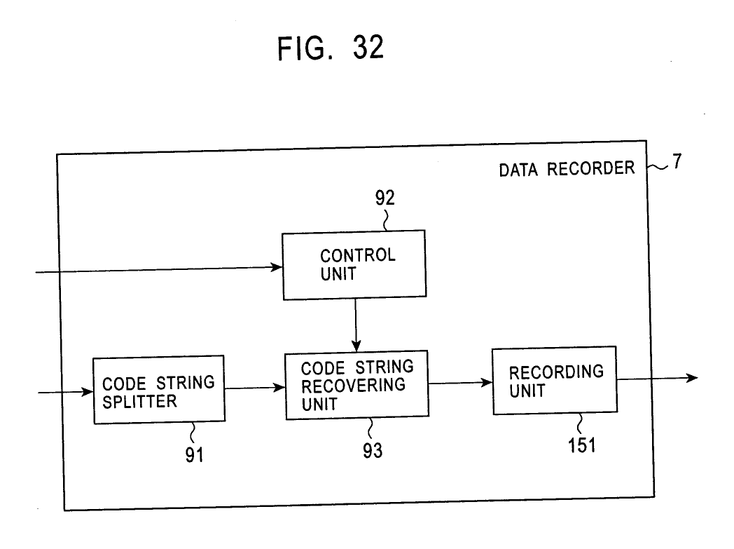

FIG. 32 is a block diagram of the configuration of the data recorder 7.

The same reference numerals are given to components corresponding to those of the data player 5 shown in FIG. 23, and repeated descriptions are appropriately omitted.

Specifically, the code string splitter 91 receives an input of encoded trial data and splits a code string into codes of signal components. Upon reception of a user's operation from an operation input unit (not shown), the control unit 92 receives an input of information indicating whether to record the input data with high sound quality, that is, whether to perform a process of recovering and recording the original data. At the same time, the control unit 92 receives an input of additional data and controls the processing by the code string recovering unit 93.

When recording the input trial data, the code string recovering unit 93 under the control of the control unit 92 recovers data in a trial area(s), which is part of data included in the extended area of each input encoded frame, and outputs the recovered data to a recording unit 151. When recovering and recording the original data, the code string recovering unit 93 under the control of the control unit 92 recovers the data included in the extended area of each input encoded frame and, on the basis of data in an additional frame supplied by the control unit 92, which is illustrated in FIG. 15 or FIG. 12, recovers the encoded frame of the original data. The code string recovering unit 93 outputs the recovered encoded frame of the original data to the recording unit 151.

The recording unit 151 records data by a predetermined method onto a recording medium, such as a magnetic disk, an optical disk, a magneto-optical disk, a semiconductor memory, or a magnetic tape. Alternatively, the recording unit 151 may record information in a built-in storage, such as a memory on a board or a hard disk. For example, when the recording unit 151 is capable of recording data onto an optical disk, the recording unit 151 includes an optical unit including an encoder for converting the data into a recording format for the optical disk, a laser light source, such as a laser diode, various lenses, and a deflecting beam splitter; a spindle motor for rotating the optical disk; a drive for driving the optical unit to a predetermined track position on the optical disk; and a controller for controlling these components.

The recording medium placed on the recording unit 151 may be the same as a recording medium having the trial data or the additional data recorded thereon, which is input to the code string splitter 91 or the control unit 92.

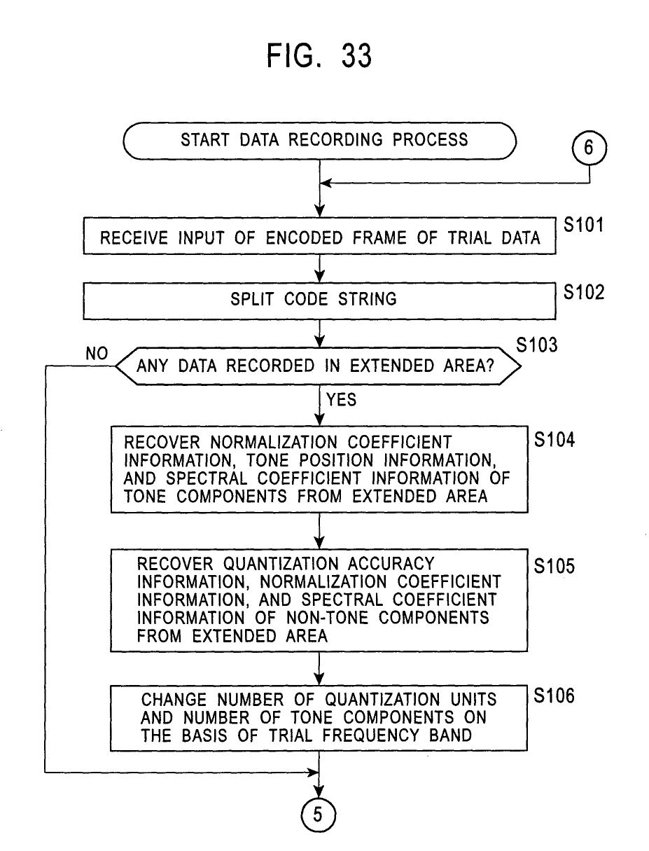

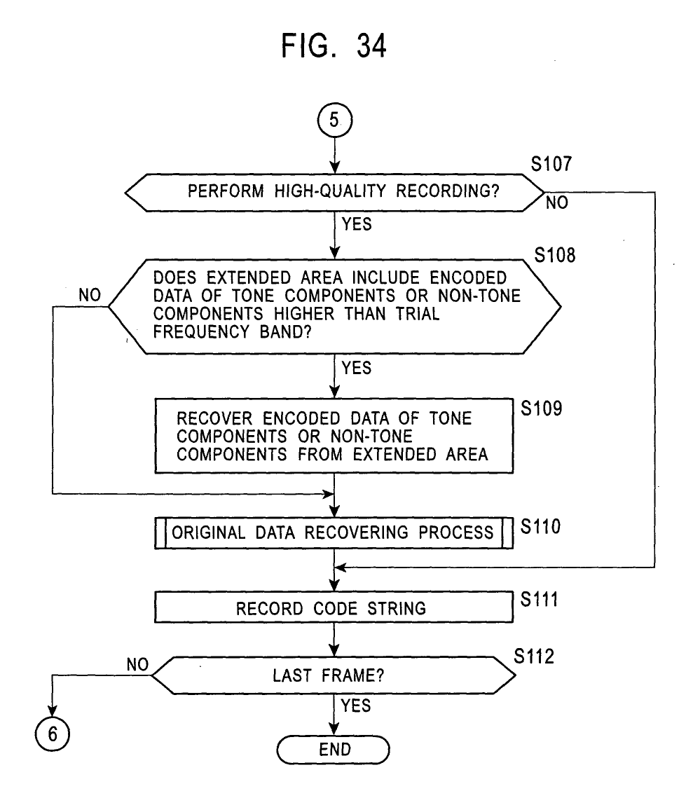

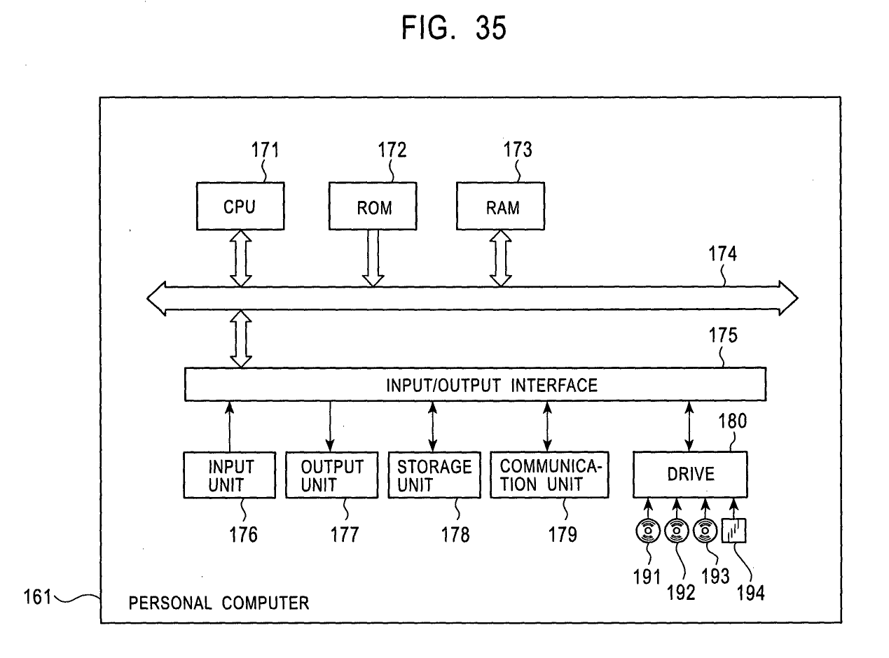

With reference to the flowcharts of FIGS. 33 and 34, a data recording process performed by the data recorder 7 will now be described.

In step S101, the code string splitter 91 receives an input of an encoded frame of the trial data. In step S102, the code string splitter 91 splits an input code string into codes and outputs the codes to the code string recovering unit 93.

In step S103, the code string recovering unit 93 determines whether or not data is recorded in the extended area of the input frame, that is, whether the input frame is a trial-permitted frame or a trial-prohibited frame.

When it is determined in step S103 that data is recorded in the extended area of the input frame, that is, the input frame is a trial-permitted frame, in steps S104 and S105, the processing similar to that in steps S55 and S56 in FIG. 29 is performed. In other words, as in the case of trial playback, data within the trial frequency band in the extended area is rearranged in a playable area.

In step S106, the code string recovering unit 93 under the control of the control unit 92 changes, on the basis of the trial frequency band, the number of quantization units and the number of tone components in the trial frame, which have been set to minimum (i.e., zero). For example, as has been illustrated in FIGS. 12 and 13, when quantization units [1] to [12] serve as the trial frequency band and only the tone component 41 is within the trial frequency band, the number of quantization units is recovered from zero to twelve, and the number of tone components is recovered from zero to one. The recovered numbers are output to the signal component decoder 94.

When it is determined in step S103 that no data is recorded in the extended area of the input frame, that is, when the input frame is a trial-prohibited frame, or subsequent to the processing in step S106, in step S107, the code string recovering unit 93 determines whether to perform high-quality recording on the basis of a signal input from the control unit 92.

When it is determined in step S107 to perform high-quality recording, in steps S108 to S110, the processing similar to that in steps S75 to S77 in FIG. 30 is performed. In other words, as in the case of high-quality playback, data higher than the trial frequency band in the extended area is rearranged in a playable area. Subsequently, the original data recovering process is performed to recover the original data on the basis of information included in the additional data.

When it is determined in step S107 not to perform high-quality recording, or subsequent to the processing in step S110, in step S111, the recording unit 151 records the input original data or a code string corresponding to the trial data on a placed recording medium or the like.

In step S112, the control unit 92 determines whether the data recorded in step S111 by the recording unit 151 is the last frame of the original data or the code string corresponding to the trial data.

When it is determined in step S112 that the data is not the last frame, the process returns to step S101, and the processing from step S101 onward is repeated. When it is determined in step S112 that the data is the last frame, the process is terminated.

According to the present invention, in each trial-permitted area, data out of the trial frequency band is separated, and the number of quantization units and the number of tone components in each trial frame are changed to minimum (i.e., zero). Data within the trial frequency band is rearranged in the extended area, which is an area that cannot be decoded by known decoding methods. Data that is not referred to during trial playback (e.g., spectral coefficient information out of the trial frequency band) is replaced with the trial time information or dummy data. Accordingly, the trial data is generated. It is very difficult to estimate the original data from such trial data. When an unauthorized alteration of the trial data is made, the sound quality is further degraded. Therefore, the rights of the creator and distributor of the content are protected.

Upon playback of the trial data, frames within the predetermined trial time are selected so that the playback start position can be changed at random. In each of the selected frames, data that is within the trial frequency band and that is in the extended area, which is an area that cannot be decoded by known decoding methods, is rearranged in an area that can be referred to during decoding, and then the data is decoded. While keeping the trial time within the predetermined time, trial playback (with low sound quality) of data at random positions on the trial data can be performed. In other words, the creator and distributor of the content can offer a trial of various portions of the trial data to users and further encourages the user to purchase this content.

The additional data including the additional frame containing data separated or replaced when the trial data is generated and information concerning such data (such as the number of separated tone components, normalization coefficient information, tone position information, and spectral coefficient information of these tone components; the number of normalization coefficients of the separated non-tone components, and quantization accuracy information and normalization coefficient information of these non-tone components; and the true spectral coefficient information of the non-tone components replaced with the trial time information or dummy data, and the position thereof). Using the additional data, the original data is recovered from the trial data.

When part or the entirety of the information included in the additional frame is written in the extended area, the volume of the additional data is reduced. For example, when a user downloads the additional data, the communication time is reduced.

According to the present invention, the trial data and the recovered original data may be played, recorded onto a recording medium, or output to another apparatus via a network or the like.

In the above description, a process of generating trial data of content data including audio signals and additional data corresponding to such trial data and a process of recovering the original data from the trial data and the additional data and playing or recording the original data have been described. The present invention is also applicable to content data including image signals or content data including image signals and audio signals.

For example, in a case in which content data including image signals is transformed using a two-dimensional DCT and quantized using various quantization tables, a dummy quantization table in which high-frequency components are missing is designated. Trial data is generated by recording, where necessary, trial time information in an area including spectral coefficient information at high frequencies corresponding to the dummy. Additional data includes the missing high-frequency components of the quantization table and the replaced spectral coefficient information.

In order to recover the original data, the true quantization table in which high-frequency components are not missing is recovered using the additional data, and the true spectral coefficient information is recovered. The original data is thus recovered and decoded.

A series of the above-described processes may be executed by hardware or software. In the latter case, for example, the encoder 4, the data player 5, or the data recorder 7 includes a personal computer 161 shown in FIG. 35.

Referring to FIG. 35, a CPU (central processing unit) 171 performs various processes in accordance with a program stored in a ROM (read only memory) 172 or a program loaded from a storage unit 178 into a RAM (random access memory) 173. The RAM 173 appropriately stores data necessary for the CPU 171 to perform these various processes.

The CPU 171, the ROM 172, and the RAM 173 are interconnected via a bus 174. An input/output interface 175 is connected to the bus 174.

An input unit 176 including a keyboard and a mouse, an output unit 177 including a display and a speaker, the storage unit 178 including a hard disk, and a communication unit 179 including a modem and a terminal adapter are connected to the input/output interface 175. The communication unit 179 performs communication via a network including the Internet.

If necessary, a drive 180 is connected to the input/output interface 175. A magnetic disk 191, an optical disk 192, a magneto-optical disk 193, or a semiconductor memory 194 is appropriately placed on the drive 180, and, where necessary, a computer program read from the placed medium is installed into the storage unit 178.

In order to perform a series of processes by software, a program forming the software is installed from a network or a recording medium into a computer included in dedicated hardware or, for example, a general-purpose personal computer capable of performing various functions by installing various programs.

As shown in FIG. 35, this recording medium includes a packaged medium that has the program recorded thereon and that is distributed separately from the apparatus to supply the program to a user. The packaged medium includes the magnetic disk 191 (including a floppy disk), the optical disk 192 (including CD-ROM (Compact Disk-Read Only Memory) and DVD (Digital Versatile Disk)), the magneto-optical disk 193 (including MD (Mini Disk) (trademark)), or the semiconductor memory 194. The recording medium also includes the ROM 172 having stored thereon the program or the hard disk included in the storage unit 178, which has been incorporated beforehand into the apparatus and then supplied to the user.

In this specification, steps for writing the program stored in the recording medium not only include time-series processing performed in accordance with the described order but also include parallel or individual processing, which may not necessarily be performed in time series.

Second Embodiment

A second embodiment of the present invention will now be described.

Hereinafter only features of the second embodiment will be described. Since the remaining portions of the second embodiment are similar to those of the first embodiment, repeated descriptions of the common portions are omitted. It is to be understood that those skilled in the art may appropriately combine the first and second embodiments to suit their business application.

During trial playback, the player for playing a signal code string according to the second embodiment decrypts an encrypted signal code string using a key, superimposes another signal on at least part of the decrypted signal code string, and plays the resultant signal code string. The signal code string to be encrypted may be generated by encoding the original signal by compressing it. The other signal to be superimposed may be a message signal.

Specifically, according to a method of the present invention, such as a playback method, apparatus, and software program according to the second embodiment, a signal generated by repeatedly superimposing a message signal on a music signal is played to offer a trial for a user. When the user listens to the music played and likes the music, the user authentically purchases a key. In such a case, this method stops superimposing the message signal. According to another method of the second embodiment of the present invention, such as a playback method, apparatus, and software program, narrowband playback of a piece of music is performed, excluding part of the piece of music. When the user listens to the piece of music played and likes the piece, the user authentically purchases a key. In such a case, this method stops performing narrowband playback.

The message signal may be superimposed or removed by various constructions to suit individual business applications. For example, the player may have a functional component for superimposing or removing the message signal. Alternatively, the server may perform the necessary processing and then performs streaming distribution.

A description will now be given using a specific example.

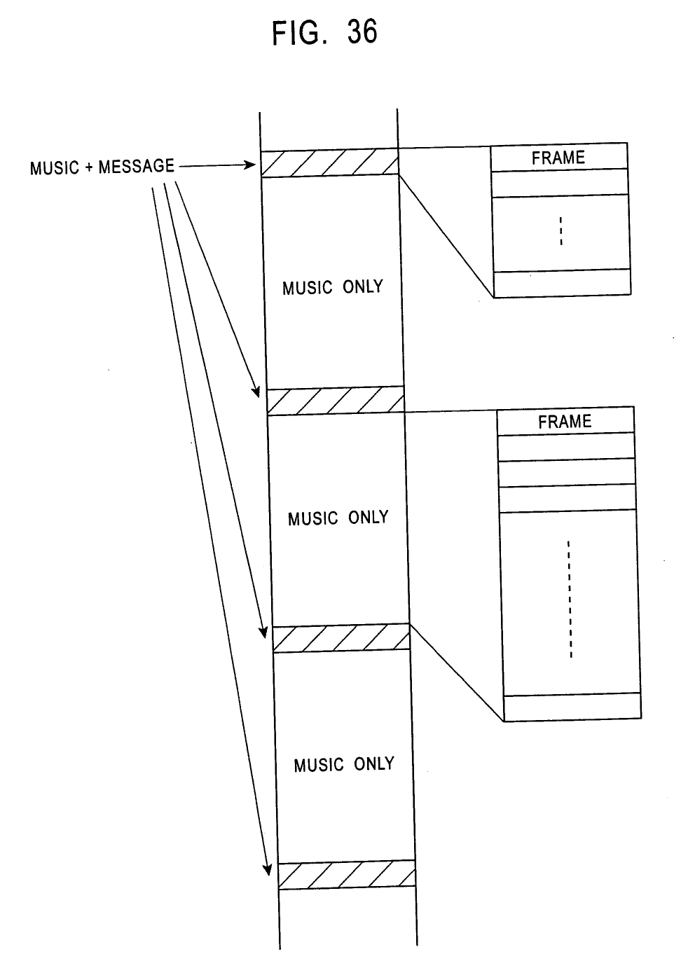

FIG. 36 illustrates an example of a signal to be decrypted and played to offer a trial. Upon trial playback, a signal generated by superimposing, for example, the message signal “This is trial data” on music at predetermined intervals is played.

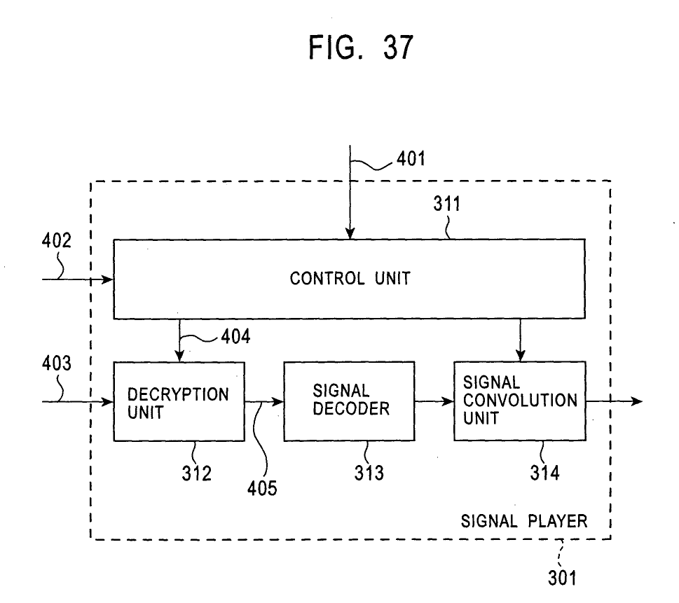

FIG. 37 shows an example of a signal player 301 according to the second embodiment. The signal player 301 is capable of selecting between two playback modes: superimposing a message signal on a music signal and playing the resultant signal; and playing a music signal without alteration. An input signal 401 is control information for controlling the signal player 301 to select between the two modes. Specifically, the input signal 401 includes information indicating whether the user is listening to a trial version of this piece of music or the user has purchased this piece of music. An input signal 402 is a key signal for decrypting an encrypted music signal code string. Preferably, the contents of the key information are stored and distributed, while hiding such contents from the outside.

To this end, for example, as is widely known, the following method is employed. A key server (not shown) and a control unit 311 each have a secret key shared by random number generator. The key server uses the random number generator to generate a random number, encrypts the random number by the secret key in accordance with, for example, data encryption standard (DES), and sends the encrypted random number to the control unit 311. The control unit 311 decrypts the sent encrypted random number using the secret key, adds one to the decrypted random number, and sends this number using the secret key in accordance with DES to the key server. The key server decrypts the number sent from the control unit 311 using the secret key and checks whether or not this number is greater than the random number generated by the key server by one. If this holds true, the key server acknowledges that the control unit 311 has the secret key and is valid. If not, the key server does not acknowledge the control unit 311 as a valid unit, and the processing from this point onward is aborted.

The key server and the control unit 311 perform the processing the other way around, and the control unit 311 authenticates that the key server is valid. After the mutual authentication, the key server encrypts a key for decrypting an encrypted music signal code string 403 by using the generated random number as a key and sends the encrypted key as the key information 402 (encrypted) to the control unit 311. The control unit 311 decrypts the key information 402 and sends key information 404 to a decryption unit 312.

The encrypted music signal code string 403 is decrypted by the decryption unit 312 using the key information 404, and then sent as a code string 405 to a signal decoder 313. The signal decoder 313 sends a decoded PCM signal to a signal convolution unit 314. In response to an instruction from the control unit 311 to perform trial playback, the signal convolution unit 314 superimposes a message signal on the decoded PCM signal and outputs the resultant signal. If the instruction from the control unit 311 indicates that the user has already purchased this music signal, the signal convolution unit 314 does not superimpose the message signal, and the PCM signal is output without being altered. In order to prevent the sum signal of the message signal and the music signal from overflowing or to prevent the message signal from being masked by the music signal, advantageously the message signal is superimposed on the music signal whose level has been reduced.

The control unit 311 includes a storage unit (not shown) that cannot be read from the outside. If a key for decrypting the encrypted music signal code string 403 is purchased, the purchased key may be stored in this storage unit, and a flag indicating that the key is purchased may be stored in this storage unit. In a case in which the control unit 311 is assumed to be satisfactorily reliable, even if the key for decrypting the encrypted music signal code string 403 is not purchased, this key may be stored in the above-described storage unit, and a flag indicating that the key is not purchased may be stored in the above-described storage unit. Preferably, a portion enclosed by the broken lines in FIG. 37 consists of, for example, a one-chip LSI (Large Scale Integration) in order to enhance security.

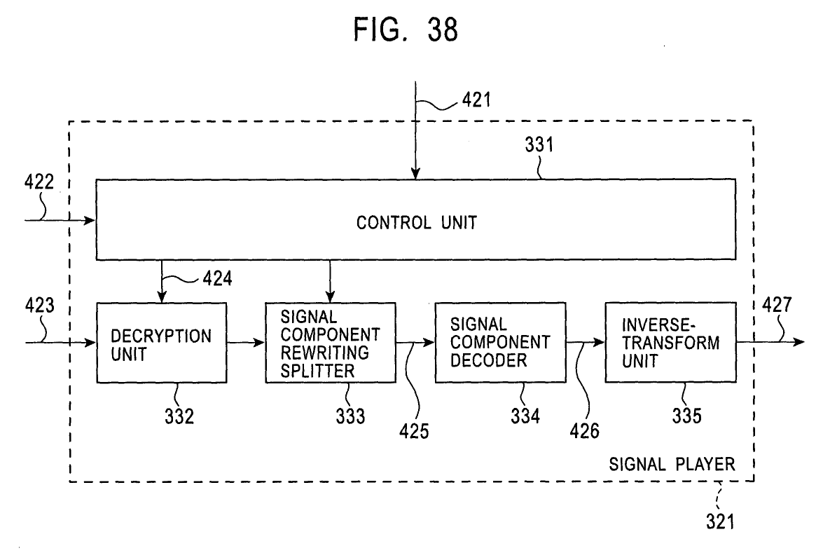

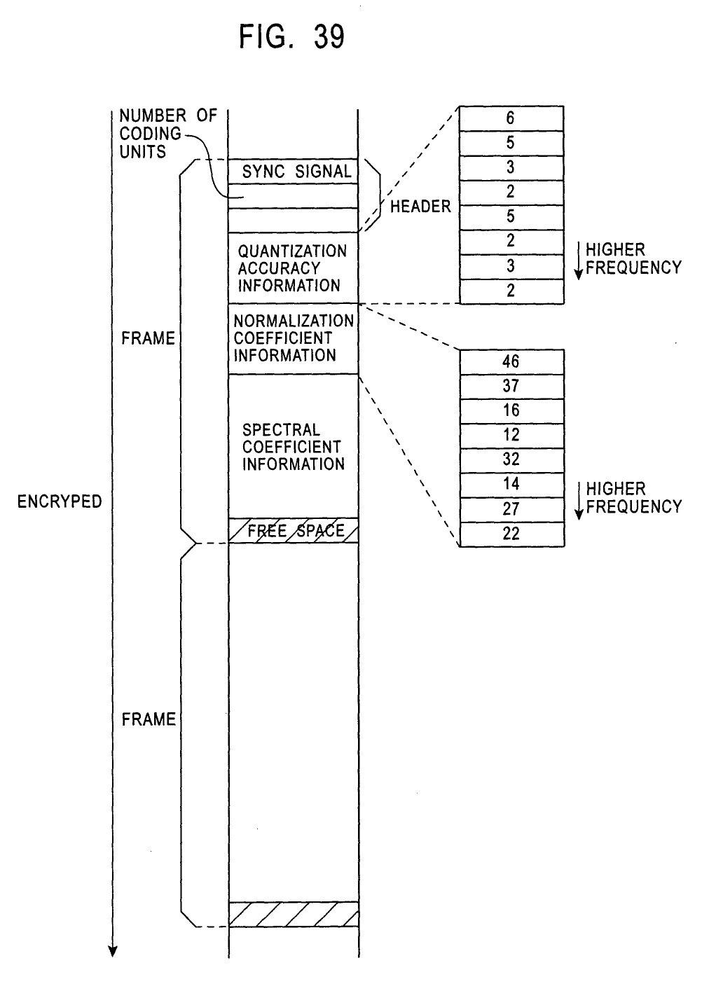

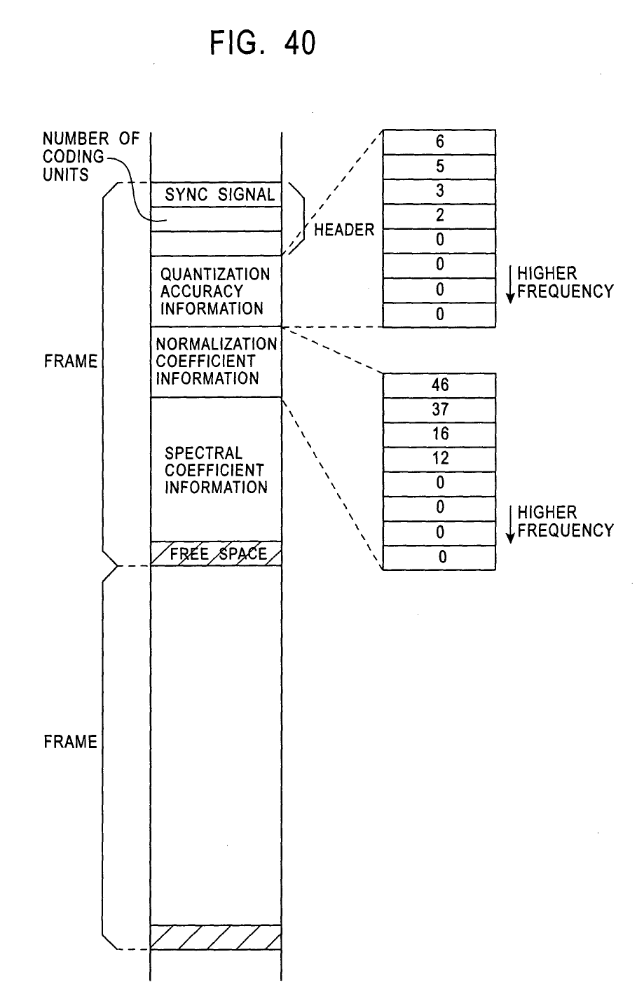

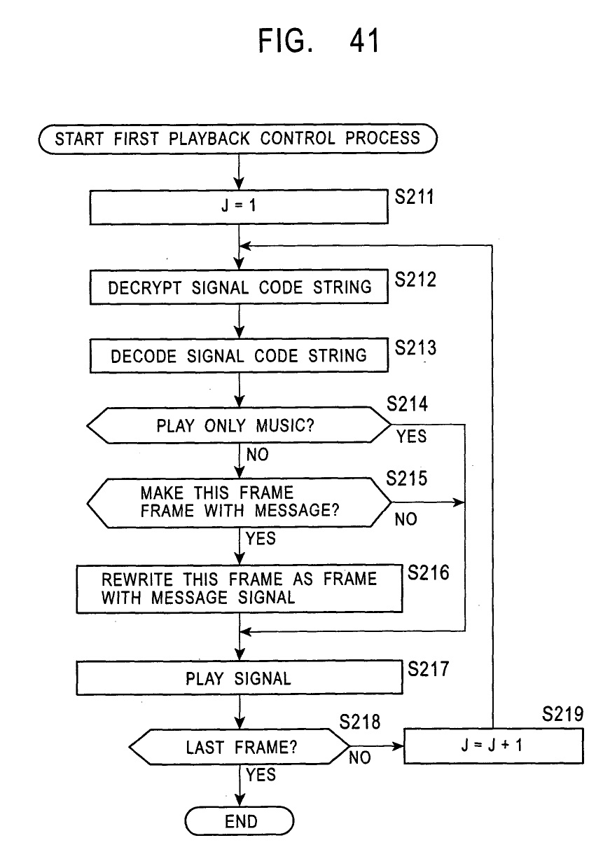

FIG. 38 shows an example of a signal player 321 according to the method of the second embodiment. The signal player 321 is capable of selecting between two playback modes for playing an input music signal code string: narrowband playback and broadband playback. An input signal 421 is control information for controlling the signal player 321 to select between the two modes. Specifically, the input signal 421 includes information indicating whether the user is listening to a trial version of this piece of music or the user has purchased this piece of music. An input signal 422 is encrypted key information for decrypting an encrypted music signal code string. Preferably, for example, the contents of the key information are transmitted by the method illustrated with reference to FIG. 37, while hiding such contents from the outside. The transmitted and encrypted key information 422 is sent to a control unit 331. The key information 422 is decrypted and sent as key information 424 to a decryption unit 332. An encrypted music signal code string 423 input to the decryption unit 332 is decrypted using the key information 424, and then sent to a signal component rewriting splitter 333. Upon narrowband playback, the signal component rewriting splitter 333 under the control of the control unit 331 rewrites, for example, decrypted code string information shown in FIG. 39 as a code string shown in FIG. 40, splits the code signal into signal components, and outputs the signal components serving as codes 425 to a signal component decoder 334.

FIG. 39 shows an example of an encoded signal code string. In this example, a fixed-length header including a sync signal is placed at the beginning of each frame. In this fixed-length header, the number of coding units is recorded. Subsequent to the header, pieces of quantization accuracy information are recorded, the number of pieces being the above-described number of coding units. Subsequent to the quantization accuracy information, pieces of normalization coefficient information are recorded, the number of pieces being the above-described number of coding units. Subsequent to the normalization coefficient information, normalized and quantized spectral coefficient information is recorded. When the frame length is fixed, there may be free space subsequent to the spectral coefficient information. In the example shown in FIG. 39, the quantization accuracy information is allocated, ranging form 6 bits in the coding unit at the lowest frequency to 2 bits in the coding unit at the highest frequency, as shown in FIG. 39. The normalization coefficient information is allocated, ranging form the value 46 in the coding unit at the lowest frequency to the value 22 in the coding unit at the highest frequency, as shown in FIG. 39. These values serving as the normalization coefficient information are in proportion to dB. The overall code string in FIG. 39 is encrypted. In order to play the code string, a key for decrypting the encrypted code string is necessary.

FIG. 40 shows a code string in which quantization accuracy information and normalization coefficient information at high frequencies are rewritten as zero. From this code string, a narrowband signal is played. The signal component decoder 334 receives codes in which some of the code components have been rewritten by the signal component rewriting splitter 333 under the control of the control unit 331 or the codes 425 in which such rewriting is not performed and decodes the received codes to generate signal components 426. These signal components 426 are sent to an inverse-transform unit 335, inverse-transformed into time-series samples, and output as a signal 427.

Band narrowing need not be done by the signal component rewriting splitter 333. For example, band narrowing may be done by the signal component decoder 334 by cutting high frequency spectra. As in the case shown in FIG. 37, a key for decrypting the encrypted music signal code string 423 or a flag indicating whether to perform narrowband playback of the signal may be stored in a satisfactorily reliable storage unit (not shown) included in the control unit 331, thus controlling the playback bandwidth of the playback signal. Band narrowing need not be done on every part of the signal and may be done only in some of the frames. This enables a user to check the sound quality when the user purchases this piece of music. Preferably, a portion enclosed by the broken lines in FIG. 38 consists of, for example, a one-chip LSI in order to enhance security.

Although both the quantization accuracy information and the normalization coefficient information are rewritten as zero in the code string shown in FIG. 40, only one of the two may be rewritten. When only the normalization coefficient information is rewritten as zero, signal components at high frequencies become very small though not exactly zero. Therefore, the playback signal is substantially a narrowband signal. The method according to the second embodiment includes a technique for rewriting a code string by rewriting the number of coding units, removing the quantization accuracy information and the normalization coefficient information at high frequencies, and moving up the spectral coefficient information.

FIG. 41 is a flowchart of a control process of selecting between playing the music signal with a message and playing only the music signal, according to the method of the second embodiment.

In step S211, the frame number J is set to one. In step S212, an encrypted music signal code string is decrypted. In step S213, the signal code string is decoded and transformed into time-series samples. In step S214, it is determined whether to play only music. If it is determined to play only music (determination is affirmative), the process proceeds to step S217. If not (determination is negative), the process proceeds to step S215. The determination may be made by determining, for example, whether the user has already purchased a decryption key for the encryption or the user is temporarily using the decryption key on a trial basis.

In step S215, it is determined whether to make this frame a frame with a message. If it is determined to make this frame a frame with a message (determination is affirmative), the process proceeds to step S216. If not (determination is negative), the process proceeds to step S217. In step S216, the music signal is rewritten as a signal with a message. In order to prevent the sum signal of the music signal and the message signal from overflowing or to prevent the message signal from being masked by the music signal, advantageously the level of the music signal is reduced.

Subsequent to the processing in step S216, the process proceeds to step S217. In step S217, a signal including the actual time-series samples is played. In step S218, it is determined whether or not this frame is the last frame. If it is determined that this frame is the last frame, the process is terminated. If not, the process proceeds to step S219, and the value of J is incremented by one. The process returns to step S212, and the processing from this step onward is repeated.

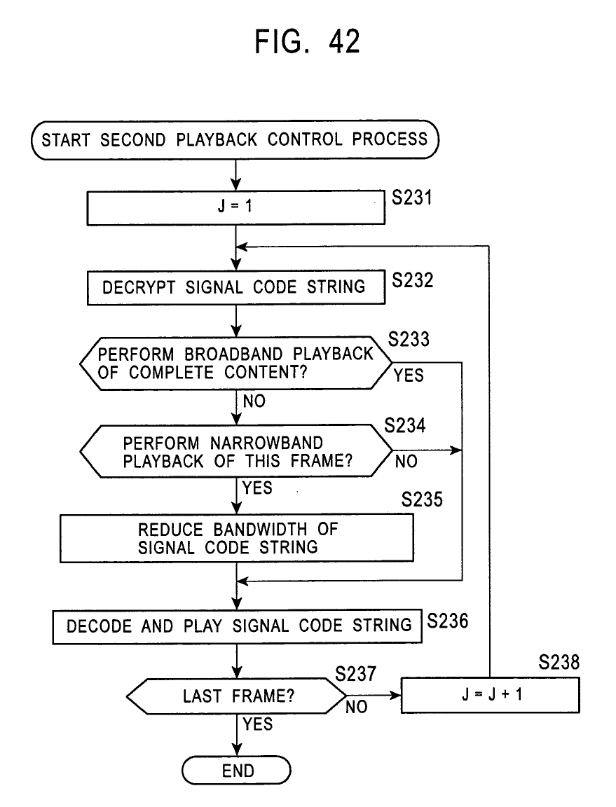

FIG. 42 is a flowchart of a control process of selecting between playing the entire music signal in broadband and playing the music signal in narrowband at least in some frames, according to the method of the second embodiment.

In step S231, the frame number J is set to one. In step S232, an encrypted music signal code string is decrypted. In step S233, it is determined whether to perform broadband playback of the complete music content. The determination may be made by determining, for example, whether the user has already purchased a decryption key for the encryption or the user is temporarily using the decryption key on a trial basis. If the determination is affirmative, the process proceeds to step S236. If the determination is negative, the process proceeds to step S234. In step S234, it is determined whether to perform narrowband playback in this frame. Narrowband playback may be performed according to a pattern established by software in which, for example, broadband playback is performed for the first thirty seconds and narrowband playback is performed for the rest of the frame. Accordingly, the user can check the sound quality when the user purchases this music content.

If the determination in step S234 is affirmative, the process proceeds to step S235. If the determination in step S234 is negative, the process proceeds to step S236. In step S235, the bandwidth of the code string is narrowed by, for example, rewriting a decrypted version of the encrypted code string shown in FIG. 39 as the code string shown in FIG. 40. In step S236, the signal code string is decoded, and a signal sound is produced. In step S237, it is determined whether or not this frame is the last frame. If the determination is affirmative, the process is terminated. If the determination is negative, in step S238, the value of J is incremented by one. The process returns to step S232, and the processing from this step onward is repeated.

Although the method of playing a trial version of an audio signal that has been encoded for compression and encrypted has been described, the method of the second embodiment is also applicable to a PCM signal that has not been particularly encoded for compression or for other purposes. In the second embodiment, the signal code string includes a signal that has remained unchanged from the original signal.

Although the case of an audio signal has been described, the method of the second embodiment is also applicable to an image signal. Specifically, for example, a trial version of image content may be offered by decrypting an encrypted image signal, and, under the control of the control unit 311 or the control unit 331, superimposing a message image on part of the image signal or cutting higher-frequency components.

What is claimed is:

1. An information processing method for an information processing apparatus receiving a supply of a second data stream generated on the basis of a first data stream and processing the second data stream, comprising:
a generation step of generating a third data stream from the second data stream on the basis of a predetermined condition; and
a first control step of controlling playback or recording of the third data stream,
wherein the second data stream has an arrangement that cannot be played or recorded without changing the arrangement, and
wherein the third data stream is generated in the generation step by rearranging, on the basis of the predetermined condition, the second data stream so that part or the entirety of the second data stream is playable or recordable.

2. An information processing method according to claim 1, wherein the predetermined condition includes a condition concerning the play time or the recording time controlled in the first control step, the upper limit of the play time or the recording time controlled in the first control step, and/or information concerning the start position of playback or recording controlled in the first control step.

3. An information processing method according to claim 1, wherein, in the generation step, the third data stream is generated so that playback or recording of an arbitrary portion of the third data stream is controlled in the first control step.

4. An information processing method according to claim 1, wherein the second data stream includes a plurality of frames, the plurality of frames including a first frame type that has a data arrangement in which data cannot be played or recorded without changing the arrangement,
wherein, in the generation step, a second frame type is selected from the first frame type of the second data stream, and data in the second frame type is rearranged so that the data in the second frame type becomes playable or recordable.

5. An information processing method according to claim 4, wherein the predetermined condition includes the upper limit of the play time or the recording time controlled in the first control step, and
wherein, in the generation step, a plurality of frames of the second frame type, which are playable or recordable within the play time or the recording time, are selected from the first frame type included in the second data stream on the basis of the predetermined condition, and data in the selected frames is rearranged.

6. An information processing method according to claim 5, wherein, in the generation step, the frames of the second frame type are selected from a plurality of portions of the second data stream so that the total play time or the total recording time is within the play time or the recording time.

7. An information processing method according to claim 1, further comprising:
a storage control step of controlling storage of information indicating the predetermined condition; and/or
an obtaining control step of controlling the obtaining of the information indicating the predetermined condition from the second data stream.

8. An information processing method according to claim 1, further comprising;
an obtaining control step of controlling the obtaining of a fourth data stream-including information required to recover the first data stream from the second data stream;
a recovering step of recovering the first data stream from the second data stream on the basis of the fourth data stream, the obtaining of which is controlled in the obtaining control step; and
a second control step of controlling playback or recording of the first data stream recovered in the recovering step.

9. An information processing method according to claim 8, wherein the fourth data stream, the obtaining of which is controlled in the obtaining control step, includes first data required to recover the first data stream, and
wherein, in the recovering step, the first data stream is recovered by replacing part of the first data included in the fourth data stream with second data included in the second data stream.

10. An information processing method according to claim 9, wherein the second data is written in the second data stream at a position not referred to when the third data stream is generated from the second data stream in the generation step and when playback or recording of the third data stream is controlled in the first control step.

11. An information processing method according to claim 9, wherein the second data stream is an encoded data stream, and
wherein the first data includes a variable-length code.

12. An information processing method according to claim 9, further comprising an inverse-transformation step of inverse-transforming frequency components,
wherein the second data stream is a data stream generated by being transformed into frequency components and then being encoded, and
wherein the first data includes spectral coefficient information.

13. An information processing method according to claim 9, further comprising a decoding step of decoding the second data stream,
wherein, when the second data is decoded in the decoding step, the data length of the decoded second data is shorter than the data length of the decoded first data.

14. An information processing method according to claim 9, wherein the second data stream is an encoded data stream, and the first data includes the number of quantization units, and/or
wherein the second data stream is a data stream generated by being separated into first signals and second signals and then being encoded, and the first data includes the number of separated first signals.

15. An information processing method according to claim 8, wherein the fourth data stream, the obtaining of which is controlled in the obtaining control step, includes data required to recover the first data stream, and
wherein, in the recovering step, the first data stream is recovered by inserting part of the data included in the fourth data stream into the second data stream.

16. An information processing method according to claim 15, wherein the second data stream is an encoded data stream, and the data included in the fourth data stream is normalization coefficient information, and/or
wherein the second data stream is an encoded data stream, and the data included in the fourth data stream is quantization accuracy information.

17. An information processing method according to claim 1, further comprising a decoding step of decoding the third data stream,
wherein, in the first control step, playback or recording of the third data stream decoded in the decoding step is controlled, and
wherein the second data stream is an encoded data stream.

18. An information processing apparatus receiving a supply of a second data stream generated on the basis of a first data stream and processing the second data stream, comprising:
generation means for generating a third data stream from the second data stream on the basis of a predetermined condition; and
control means for controlling playback or recording of the third data stream.

19. A program executable by a computer for controlling an information processing apparatus receiving a supply of a second data stream generated on the basis of a first data stream and processing the second data stream, the program comprising:
a generation step of generating a third data stream from the second data stream on the basis of a predetermined condition; and
a control step of controlling playback or recording of the third data stream.

20. An information processing method for an information processing apparatus transforming a first data stream into a second data stream, comprising:
a first replacement step of replacing first data included in the first data stream with second data to generate a third data stream;
a changing step of changing the arrangement of third data included in the third data stream generated in the first replacement step;
an insertion step of inserting information indicating a condition for playback or recording of the second data stream into the third data stream in which the arrangement of the third data is changed in the changing step; and
a first generation step of generating the second data stream on the basis of the third data stream including the information indicating the condition, the information being inserted in the insertion step,
wherein, in the changing step, the third data recorded in a first area of the third data stream is moved to a second area.

21. An information processing method according to claim 20, wherein the first area is an area that is in the third data stream and that is associated with an area referred to during playback or recording of the second data stream generated in the first generation step, and
wherein the second area is an area that is in the third data stream and that is associated with an area not referred to during playback or recording of the second data stream generated in the first generation step.

22. An information processing method according to claim 21, wherein the second area is an area that is in the third data stream and that, by replacing the first data with the second data in the first replacement step, becomes associated with an area not referred to during playback or recording of the second data stream.

23. An information processing method according to claim 22, wherein the first data is data concerning the number of pieces of information referred to during playback or recording of the second data stream, and
wherein, in the first replacement step, the first data is replaced with the second data indicating that there is no information referred to during playback or recording of the second data stream.

24. An information processing method according to claim 20, wherein the first data stream, the second data stream, and the third data stream each include a plurality of frames,
wherein, in the insertion step, the information indicating the condition is inserted into at least one of the plurality of frames of the third data stream, and
wherein the frames included in the second data stream generated in the first generation step include information indicating whether or not the information indicating the condition is inserted in the insertion step.

25. An information processing method according to claim 20, wherein the information indicating the condition, which is inserted into the third data stream in the insertion step, includes a condition concerning the play time or the recording time when playing or recording the second data stream and/or information concerning the start position of playback or recording when playing or recording the second data stream.

26. An information processing method according to claim 20, further comprising a separation step of separating fourth data from the first data stream, the fourth data differing from the first data and the third data.

27. An information processing method according to claim 26, further comprising an encoding step of encoding input data,
wherein the fourth data includes normalization coefficient information on the encoding in the encoding step and/or quantization accuracy information on the encoding in the encoding step.

28. An information processing method according to claim 20, further comprising a second generation step of generating a fourth data stream required to recover the first data stream from the second data stream generated in the first generation step,
wherein the fourth data stream generated in the second generation step includes the first data replaced with the second data in the first replacement step.

29. An information processing method according to claim 28, further comprising a separation step of separating fourth data from the first data stream, the fourth data differing from the first data and the third data,
wherein the fourth data stream generated in the second generation step further includes the fourth data separated in the separation step.

30. An information processing method according to claim 20, further comprising an encoding step of encoding input data,
wherein, in the first replacement step, encoded data encoded in the encoding step serves as the first data stream, and the first data included in the first data stream is replaced with the second data.

31. An information processing method according to claim 30, wherein the first data includes information indicating the number of quantization units in the encoding in the encoding step.

32. An information processing method according to claim 30, further comprising:
a frequency component transformation step of transforming input data into frequency components; and
a separation step of separating the frequency components generated by transformation in the frequency component transformation step into first signals including tone components and second signals other than the first signals,
wherein, in the encoding step, different encoding processes are performed on the first signals and the second signals.

33. An information processing method according to claim 32, wherein the first data is data indicating the number of first signals separated in the separation step.

34. An information processing method according to claim 20, further comprising a second replacement step of replacing fourth data with fifth data, the fourth data differing from the first data included in the first data stream,
wherein the fifth data is associated with data not referred to during playback or recording of the second data, and
wherein, in the changing step, the arrangement of the third data included in the third data stream in which the fourth data is replaced with the fifth data in the second replacement step is changed.

35. An information processing method according to claim 34, wherein the fifth data is generated by replacing at least part of the fourth data with random data.

36. An information processing method according to claim 34, further comprising a second generation step of generating a fourth data stream required to recover the first data stream from the second data stream generated in the first generation step,
wherein the fourth data stream generated in the second generation step includes the fourth data replaced with the fifth data in the second replacement step and position information indicating the position of the fourth data in the first data stream.

37. An information processing method according to claim 34, further comprising an encoding step of encoding data,
wherein, when the fifth data is decoded, the data length of the decoded fifth data is shorter than the data length of the decoded fourth data.

38. An information processing method according to claim 34, further comprising an encoding step of encoding data,
wherein the fourth data includes a variable-length code.

39. An information processing apparatus transforming a first data stream into a second data stream, comprising:
replacement means for replacing first data included in the first data stream with second data to generate a third data stream;
changing means for changing the arrangement of third data included in the third data stream generated by the replacement means;
insertion means for inserting information indicating a condition for playback or recording of the second data stream into the third data stream in which the arrangement of the third data is changed by the changing means; and
generation means for generating the second data stream on the basis of the third data stream including the information indicating the condition, the information being inserted by the insertion means,
wherein the changing means moves the third data recorded in a first area of the third data stream to a second area.

40. A program executable by a computer for controlling an information processing apparatus transforming a first data stream into a second data stream, comprising:
a replacement step of replacing first data included in the first data stream with second data to generate a third data stream;
a changing step of changing the arrangement of third data included in the third data stream generated in the replacement step;
an insertion step of inserting information indicating a condition for playback or recording of the second data stream into the third data stream in which the arrangement of the third data is changed in the changing step; and
a generation step of generating the second data stream on the basis of the third data stream including the information indicating the condition, the information being inserted in the insertion step,
wherein, in the changing step, the third data recorded in a first area of the third data stream is moved to a second area.
